(19) United States
(12) Patent Application Publication
(10) Pub. No.: US 2025/0221223 A1
(43) Pub. Date: Jul. 3, 2025

(54) DISPLAY APPARATUS

(71) Applicant: SAMSUNG DISPLAY CO., LTD., Yongin-si (KR)

(72) Inventor: Haeyoung Yun, Yongin-si (KR)

(21) Appl. No.: 18/755,283

(22) Filed: Jun. 26, 2024

(30) Foreign Application Priority Data
Dec. 29, 2023 (KR) 10-2023-0197216

(51) Int. Cl. H10K 59/38; H10K 59/122; H10K 59/35; H10K 59/80

(52) U.S. Cl. CPC H10K 59/38; H10K 59/122; H10K 59/353; H10K 59/873; H10K 59/8792

(57) ABSTRACT

A display apparatus includes a substrate, a plurality of sub-pixels that include a first-color sub-pixel, a second-color sub-pixel, and a third-color sub-pixel that each include a sub-pixel electrode, a bank layer that includes a plurality of lower openings that define an emission area in each of the plurality of sub-pixels, an encapsulation layer disposed on the bank layer, and a plurality of color filters disposed on the encapsulation layer and that include a first-color color filter, a second-color color filter, and a third-color color filter. The first-color sub-pixel includes a first-1 color sub-pixel and a first-2 color sub-pixel that emit light of a same color and are adjacent to each other, and a vertical distance between the substrate and a sub-pixel electrode of the first-1 color sub-pixel differs from a vertical distance between the substrate and a sub-pixel electrode of the first-2 color sub-pixel.

### CROSS-REFERENCE TO RELATED APPLICATION

This application claims priority under 35 U.S.C. § 119 from Korean Patent Application No. 10-2023-0197216, filed on Dec. 29, 2023 in the Korean Intellectual Property Office, the contents of which are herein incorporated by reference in their entirety.

### TECHNICAL FIELD

One or more embodiments are directed to a display apparatus.

### DISCUSSION OF THE RELATED ART

Display apparatuses visually display data. A display apparatus can be used as a display unit of a miniaturized product such as a mobile phone or a large product such as a television.

A display apparatus includes a plurality of sub-pixels that receive electrical signals and emit light to display images. Each sub-pixel includes a light-emitting element. For example, an organic light-emitting display apparatus includes an organic light-emitting diode (OLED) as a light-emitting element. In general, an organic light-emitting display apparatus includes a thin-film transistor and an organic light-emitting diode disposed over a substrate, and operates when the organic light-emitting diode emits light.

### SUMMARY

One or more embodiments include a display apparatus with reduced visibility of multiple images caused by external light reflection and diffraction. However, such a technical problem is an example, and embodiments of the disclosure are not necessarily limited thereto.

According to one or more embodiments, a display apparatus includes a substrate, a plurality of sub-pixels that include a first-color sub-pixel, a second-color sub-pixel, and a third-color sub-pixel that each include a sub-pixel electrode, an emission layer disposed on the sub-pixel electrode, and an opposite electrode disposed on the emission layer, a bank layer that includes a plurality of lower openings that define an emission area in each of the plurality of sub-pixels, an encapsulation layer disposed on the bank layer and that includes an organic encapsulation layer, and a plurality of color filters disposed on the encapsulation layer and that include a first-color color filter, a second-color color filter, and a third-color color filter, wherein the first-color sub-pixel includes a first-1 color sub-pixel and a first-2 color 19

ub-pixel that emit light of a same color and are adjacent to each other, and a vertical distance between the substrate and a sub-pixel electrode of the first-1 color sub-pixel differs from a vertical distance between the substrate and a sub-pixel electrode of the first-2 color sub-pixel.

The display apparatus may further include a light-blocking layer disposed between the bank layer and the plurality of color filters and that includes a plurality of upper openings that respectively overlap the plurality of lower openings.

The display apparatus does not include a polarizing film.

The plurality of sub-pixels may include a repeated configuration structure of a sub-pixel pattern unit block that include the first-color sub-pixel, the second-color sub-pixel, and the third-color sub-pixel, and a number ratio of the first-color sub-pixel, the second-color sub-pixel, and the third-color sub-pixel in the sub-pixel pattern unit block may be 2:1:1.

A difference Δhg between a first-1 vertical distance from the substrate to the sub-pixel electrode of the first-1 color sub-pixel and a first-2 vertical distance from the substrate to the sub-pixel electrode of the first-2 color sub-pixel may satisfy a following equation:

$$Δ hg = hg 1 - hg 2 = ( \pm \frac{1}{8 n 0} + \frac{m}{2 n 0} ) \cdot λ1 ,$$

wherein m is an integer
n0 is a refractive index of the organic encapsulation layer, λ1 is a wavelength of light reflected by the first-1 color sub-pixel and the first-2 color sub-pixel a vacuum, hg1 is the first-1 vertical distance from the substrate to the sub-pixel electrode of the first-1 color sub-pixel, and hg2 is the first-2 vertical distance from the substrate to the sub-pixel electrode of the first-2 color sub-pixel.

The first-color sub-pixel may further include a first-3 color sub-pixel and a first-4 color sub-pixel that emit light of same color and are adjacent to each other, and a first-1 vertical distance from the substrate to the sub-pixel electrode of the first-1 color sub-pixel, a first-2 vertical distance from the substrate to the sub-pixel electrode of the first-2 color sub-pixel, a first-3 vertical distance from the substrate to a sub-pixel electrode of the first-3 color sub-pixel, and a first-4 vertical distance from the substrate to a sub-pixel electrode of the first-4 color sub-pixel may be different from each other.

A difference Δhg(1) between the first-1 vertical distance from the substrate to the sub-pixel electrode of the first-1 color sub-pixel and the first-2 vertical distance from the substrate to the sub-pixel electrode of the first-2 color sub-pixel, a difference Δhg(2) between the first-1 vertical distance from the substrate to the sub-pixel electrode of the first-1 color sub-pixel and the first-3 vertical distance from the substrate to the sub-pixel electrode of the first-3 color sub-pixel, and a difference Δhg(3) between the first-1 vertical distance from the substrate to the sub-pixel electrode of the first-1 color sub-pixel and the first-4 vertical distance from the substrate to the sub-pixel electrode of the first-4 color sub-pixel, may satisfy equations as follows:

$$Δ hg ( 1 ) = hg 1 - hg 2 = ( \frac{\pm 1}{16 n 0} + \frac{m}{2 n 0} ) \cdot λ1 , ,$$

wherein m is an integer,

$$Δ hg ( 2 ) = hg 1 - hg 3 = ( \frac{\pm 1}{8 n 0} + \frac{m}{2 n 0} ) \cdot λ1 ,$$

wherein m is an integer,

$$Δ hg ( 3 ) = hg 1 - hg 4 = ( \frac{\pm 3}{16 n 0} + \frac{m}{2 n 0} ) \cdot λ1 ,$$

wherein m is an integer,
n0 is a refractive index of the organic encapsulation layer, λ1 is a wavelength of light reflected by the first-1 color sub-pixel to the first-4 color sub-pixel in a vacuum, hg1 is the first-1 vertical distance from the substrate to the sub-pixel electrode of the first-1 color sub-pixel, hg2 is the first-2 vertical distance from the substrate to the sub-pixel electrode of the first-2 color sub-pixel, and hg3 is the first-3 vertical distance from the substrate to the sub-pixel electrode of the first-3 color sub-pixel, hg4 is the first-4 vertical distance from the substrate to the sub-pixel electrode of the first-4 color sub-pixel.

The second-color sub-pixel may include a second-1 color sub-pixel and a second-2 color sub-pixel that emit light of same color and are adjacent to each other, and a second-1 vertical distance from the substrate to a sub-pixel electrode of the second-1 color sub-pixel may differ from a second-2 vertical distance from the substrate to a sub-pixel electrode of the second-2 color sub-pixel.

The third-color sub-pixel may include a third-1 color sub-pixel and a third-2 color sub-pixel that emit light of same color and are adjacent to each other, and a third-1 vertical distance from the substrate to a sub-pixel electrode of the third-1 color sub-pixel may differ from a third-2 vertical distance from the substrate to a sub-pixel electrode of the third-2 color sub-pixel.

A difference Δhb between the second-1 vertical distance from the substrate to the sub-pixel electrode of the second-1 color sub-pixel and the second-2 vertical distance from the substrate to the sub-pixel electrode of the second-2 color sub-pixel may satisfy a following equation:

$$Δ hb = hb 1 - hb 2 = ( \pm \frac{1}{8 n 0} + \frac{k}{2 n 0} ) \cdot λ2 ,$$

wherein k is an integer,
n0 is a refractive index of the organic encapsulation layer, λ2 is a wavelength of light reflected by the second-1 color sub-pixel and the second-2 color sub-pixel in a vacuum, hb1 is a second-1 vertical distance from the substrate to the sub-pixel electrode of the second-1 color sub-pixel, and hb2 is a second-2 vertical distance from the substrate to the sub-pixel electrode of the second-2 color sub-pixel.

A difference Δhr between the third-1 vertical distance from the substrate to the sub-pixel electrode of the third-1 color sub-pixel and the third-2 vertical distance from the substrate to the sub-pixel electrode of the third-2 color sub-pixel may satisfy a following equation:

$$Δ hr = hr 1 - hr 2 = ( \pm \frac{1}{8 n 0} + \frac{l}{2 n 0} ) \cdot λ3 ,$$

wherein l is an integer,
n0 is a refractive index of the organic encapsulation layer, λ3 is a wavelength of light reflected by the third-1 color sub-pixel and the third-2 color sub-pixel in a vacuum, hr1 is a third-1 vertical distance from the substrate to the sub-pixel electrode of the third-1 color sub-pixel, and hr2 is a third-2 vertical distance from the substrate to the sub-pixel electrode of the third-2 color sub-pixel.

The plurality of sub-pixels may include a repeated configuration structure of a sub-pixel pattern unit block that includes the first-color sub-pixel, the second-color sub-pixel, and the third-color sub-pixel, and a number ratio of the first-color sub-pixel, the second-color sub-pixel, and the third-color sub-pixel in the sub-pixel pattern unit block may be 1:1:1.

A difference Δhg between a first-1 vertical distance from the substrate to the sub-pixel electrode of the first-1 color sub-pixel and a first-2 vertical distance from the substrate to the sub-pixel electrode of the first-2 color sub-pixel may satisfy a following equation:

$$Δ hg = hg 1 - hg 2 = ( \pm \frac{1}{8 n 0} + \frac{m}{2 n 0} ) \cdot λ1 ,$$

wherein m is an integer,
n0 is a refractive index of the organic encapsulation layer, λ1 is a wavelength of light reflected by the first-1 color sub-pixel and the first-2 color sub-pixel in a vacuum, hg1 is the first-1 vertical distance from the substrate to the sub-pixel electrode of the first-1 color sub-pixel, and hg2 is the first-2 vertical distance from the substrate to the sub-pixel electrode of the first-2 color sub-pixel.

The second-color sub-pixel may include a second-1 color sub-pixel and a second-2 color sub-pixel that emits light of same color and are adjacent to each other, and a second-1 vertical distance from the substrate to a sub-pixel electrode of the second-1 color sub-pixel may differ from a second-2 vertical distance from the substrate to a sub-pixel electrode of the second-2 color sub-pixel.

The third-color sub-pixel may include a third-1 color sub-pixel and a third-2 color sub-pixel that emit light of same color and are adjacent to each other, and a third-1 vertical distance from the substrate to a sub-pixel electrode of the third-1 color sub-pixel may differ from a third-2 vertical distance from the substrate to a sub-pixel electrode of the third-2 color sub-pixel.

A difference Δhb between the second-1 vertical distance from the substrate to the sub-pixel electrode of the second-1 color sub-pixel and the second-2 vertical distance from the substrate to the sub-pixel electrode of the second-2 color sub-pixel may satisfy a following equation:

$$Δ hb = hb 1 - hb 2 = ( \pm \frac{1}{8 n 0} + \frac{k}{2 n 0} ) \cdot λ2 ,$$

wherein k is an integer,
n0 is a refractive index of the organic encapsulation layer, λ2 is a wavelength of light reflected by the second-1 color sub-pixel and the second-2 color sub-pixel in a vacuum, hb1 is a second-1 vertical distance from the substrate to the sub-pixel electrode of the second-1 color sub-pixel, and hb2 is a second-2 vertical distance from the substrate to the sub-pixel electrode of the second-2 color sub-pixel.

A difference Δhr between the third-1 vertical distance from the substrate to the sub-pixel electrode of the third-1 color sub-pixel and the third-2 vertical distance from the substrate to the sub-pixel electrode of the third-2 color sub-pixel may satisfy a following equation:

$$Δ hr = hr 1 - hr 2 = ( \pm \frac{1}{8 n 0} + \frac{l}{2 n 0} ) \cdot λ3 ,$$

wherein l is an integer,
n0 is a refractive index of the organic encapsulation layer, λ3 is a wavelength of light reflected by the third-1 color sub-pixel and the third-2 color sub-pixel in a vacuum, hr1 is a third-1 vertical distance from the substrate to the sub-pixel electrode of the third-1 color sub-pixel, and hr2 is a third-2 vertical distance from the substrate to the sub-pixel electrode of the third-2 color sub-pixel.

The first-color color filter, the second-color color filter, and the third-color color filter may overlap each other in a region between the sub-pixel electrodes of the plurality of sub-pixels.

The first-color sub-pixel may be an elliptical shape in a plan view, and the first-color sub-pixel may include a first-axis sub-pixel and a second-axis sub-pixel that have different elliptical axis angles from each other.

Each of the first-color sub-pixel, the second-color sub-pixel, and the third-color sub-pixel may have an elliptical shape in a plan view, and at least two of the first-color sub-pixel, the second-color sub-pixel, or the third-color sub-pixel may have different elliptical eccentricities from each other.

### BRIEF DESCRIPTION OF THE DRAWINGS

FIG. 1 is a schematic perspective view of a display apparatus according to an embodiment.

FIG. 2 illustrates a light-emitting diode of a sub-pixel of a display apparatus and a sub-pixel circuit connected thereto according to an embodiment.

FIG. 3 is a schematic cross-sectional view of a display apparatus taken along line I-I′ of FIG. 1, according to an embodiment.

FIG. 4 is a schematic cross-sectional view of a display apparatus according to an embodiment.

FIG. 5 is a schematic cross-sectional view of a display apparatus according to an embodiment.

FIG. 6 is a plan view of sub-pixels of a display apparatus according to an embodiment.

FIG. 7 illustrates a multiple image phenomenon caused by external light reflection and diffraction of a display apparatus.

FIG. 8 is a plan view of sub-pixels of a display apparatus according to an embodiment.

FIG. 9 is a schematic cross-sectional view of a display apparatus according to an embodiment.

FIG. 10 is a plan view of sub-pixels of a display apparatus according to an embodiment.

FIG. 11 is a schematic cross-sectional view of a display apparatus according to an embodiment.

FIG. 12 is a schematic cross-sectional view of a display apparatus according to an embodiment.

FIG. 13 is a schematic cross-sectional view of a display apparatus according to an embodiment.

FIG. 14 is a plan view of sub-pixels of a display apparatus according to an embodiment.

FIG. 15 is a plan view of sub-pixels of a display apparatus according to an embodiment.

FIG. 16 is a schematic cross-sectional view of a display apparatus according to an embodiment.

FIG. 17 is a schematic cross-sectional view of a display apparatus according to an embodiment.

FIG. 18 is a schematic cross-sectional view of a display apparatus according to an embodiment.

FIG. 19 is a plan view of sub-pixels of a display apparatus according to an embodiment.

FIG. 20 is a plan view of sub-pixels of a display apparatus according to an embodiment.

### DETAILED DESCRIPTION

Reference will now be made in detail to embodiments, examples of which are illustrated in the accompanying drawings, wherein like reference numerals may refer to like elements throughout.

However, the disclosure is not necessarily limited to the following embodiments and may be embodied in various other forms.

Hereinafter, embodiments will be described with reference to the accompanying drawings, wherein like reference numerals may refer to like elements throughout and a repeated description thereof is omitted.

It will be further understood that, when a layer, region, or element is referred to as being “on” another layer, region, or element, it can be directly or indirectly on the other layer, region, or element.

It will be understood that when a layer, region, or element is referred to as being “connected” to another layer, region, or element, it may be “directly connected” to the other layer, region, or element or may be “indirectly connected” to the other layer, region, or element with another layer, region, or element located therebetween

The x-axis, the y-axis and the z-axis are not limited to three axes of the rectangular coordinate system, and may be interpreted in a broader sense. For example, the x-axis, the y-axis, and the z-axis may be perpendicular to one another, or may represent different orientations that are not perpendicular to one another.

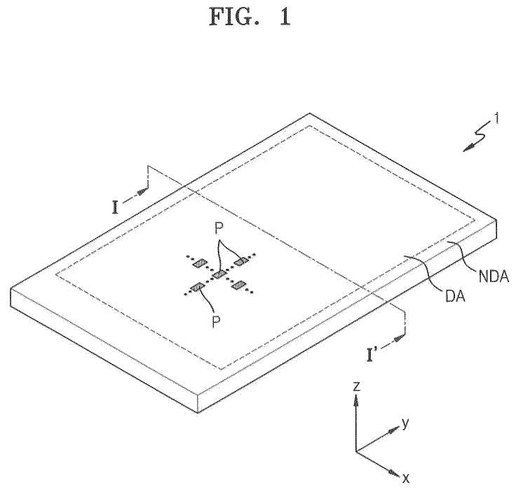

FIG. 1 is a schematic perspective view of a display apparatus 1 according to an embodiment.

Referring to FIG. 1, in an embodiment, the display apparatus 1 includes a display area DA and a peripheral area NDA outside the display area DA. The display apparatus 1 can display images through an array of a plurality of sub-pixels P arranged two-dimensionally in the display area DA.

Each sub-pixel P of the display apparatus 1 emits light of a preset color. The display apparatus 1 display images using light emitted from the sub-pixels P. For example, each sub-pixel P emits one of red, green, blue, or white light.

Each of the sub-pixels emits light of a preset color using a light-emitting diode, such as an organic light-emitting diode. Each organic light-emitting diode emits, for example, one of red, green, blue, or white light. Each organic light-emitting diode is connected to a sub-pixel circuit that includes a thin-film transistor and a capacitor.

The peripheral area NDA does not display images and surrounds the display area DA. In an embodiment, the peripheral area NDA entirely surrounds the display area DA. A driver or a main power line that provides electric signals or power to sub-pixel circuits is disposed in the peripheral area NDA. A pad is disposed in the peripheral area NDA, and electronic elements or a printed circuit board can be electrically connected to the pad.

As shown in FIG. 1, the display area DA has a polygonal shape, such as a rectangular shape. For example, the display area DA may have a rectangular shape in which a horizontal length thereof is greater than a vertical length, a rectangular shape in which a horizontal length thereof is less than a vertical length, or a square shape. In other embodiments, the display area DA can have various other shapes such as an elliptical shape or a circular shape.

The display apparatus 1 can be incorporated into mobile phones, televisions, billboards, tablet personal computers, laptop computers, smartwatches, smartbands worn on the wrist, etc.

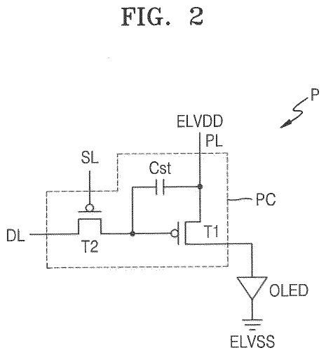

FIG. 2 illustrates a light-emitting diode of a sub-pixel of the display apparatus 1, and a sub-pixel circuit connected thereto according to an embodiment.

Referring to FIG. 2, in an embodiment, an organic light-emitting diode OLED, which is a light-emitting diode, is connected to a sub-pixel circuit PC. The sub-pixel circuit PC includes a first thin-film transistor T1, a second thin-film transistor T2, and a storage capacitor Cst.

The second thin-film transistor T2 is a switching thin-film transistor, is connected to a scan line SL and a data line DL, and transmits a data voltage to the first thin-film transistor T1 according to a switching voltage. The data voltage is received from the data line DL, and the switching voltage is received from the scan line SL. The storage capacitor Cst is connected to the second thin-film transistor T2 and a driving voltage line PL and stores a voltage that corresponds to a difference between a voltage received from the second thin-film transistor T2 and a driving voltage ELVDD received from the driving voltage line PL.

The first thin-film transistor T1 is a driving thin-film transistor, is connected to the driving voltage line PL and the storage capacitor Cst, and controls a driving current according to the voltage stored in the storage capacitor Cst. The driving current flows from the driving voltage line PL to the organic light-emitting diode OLED. The organic light-emitting diode OLED emits light that has a preset brightness that corresponds to the driving current. A sub-pixel electrode, such as an anode, of the organic light-emitting diode OLED is connected to the sub-pixel circuit PC. An opposite electrode, such as a cathode, of the organic light-emitting diode OLED receives a common voltage ELVSS.

Although FIG. 2 shows that the sub-pixel circuit PC includes two thin-film transistors and one storage capacitor, the number of thin-film transistors or the number of storage capacitors can be variously changed depending on the design of the sub-pixel circuit PC.

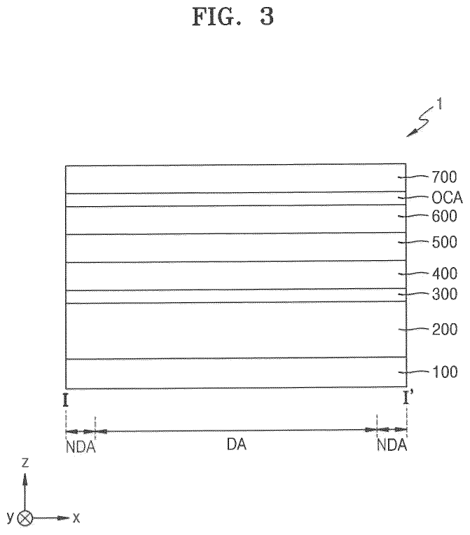

FIG. 3 is a schematic cross-sectional view of the display apparatus 1, taken along line I-I′ of FIG. 1, according to an embodiment.

Referring to FIG. 3, in an embodiment, the display apparatus 1 includes a substrate 100, a display layer 200, a low-reflective layer 300, an encapsulation layer 400, a touch sensor layer 500, an anti-reflection layer 600, an adhesive layer OCA, and a cover window 700.

The substrate 100 includes at least one of glass or a polymer resin. For example, the polymer resin includes at least one of polyethersulfone, polyacrylate, polyetherimide, polyethylene naphthalate, polyethylene terephthalate, polyphenylene sulfide, polyarylate, polyimide, polycarbonate, or cellulose acetate propionate, etc. The polymer resin substrate 100 is flexible, rollable, or bendable. The substrate 100 may have a multi-layered structure that includes a layer that includes a polymer resin and an inorganic layer.

The display layer 200 is disposed on substrate 100 and includes a light-emitting diode, a thin-film transistor, and insulating layers therebetween. The thin-film transistor is electrically connected to the light-emitting diode, such as an organic light-emitting diode.

The low-reflective layer 300 is disposed on the display layer 200, and the encapsulation layer 400 is disposed on the low-reflective layer 300. For example, the display layer 200 and/or the low-reflective layer 300 are sealed by the encapsulation layer 400. In an embodiment, the low-reflective layer 300 is omitted. For example, the encapsulation layer 400 is directly disposed on the display layer 200. The encapsulation layer 400 includes at least one inorganic encapsulation layer and at least one organic encapsulation layer.

In an embodiment, an encapsulation substrate (that includes glass is provided instead of the encapsulation layer 400. The encapsulation substrate is disposed on the display layer 200, and the display layer 200 is disposed between the substrate 100 and the encapsulation substrate. There may be a gap between the encapsulation substrate and the display layer 200. A filling material may fill the gap.

The touch sensor layer 500 is disposed on the encapsulation layer 400. The touch sensor layer 500 can sense an external input, such as a touch of an object such as a finger or a stylus pen, and the display apparatus 1 obtains coordinate information that corresponds to the touched position. The touch sensor layer 500 includes a touch electrode and touch lines connected to the touch electrode. The touch sensor layer 500 senses an external input by using a self-capacitance method or a mutual capacitance method.

The touch sensor layer 500 is directly disposed on the encapsulation layer 400. However, in an embodiment, the touch sensor layer 500 is formed separately and then attached to the encapsulation layer 400 by an adhesive layer such as an optically clear adhesive.

The anti-reflection layer 600 is disposed on the touch sensor layer 500. The anti-reflection layer 600 reduces the reflectivity of external light incident on the display apparatus 1 through the cover window 700.

The anti-reflection layer 600 includes a light-blocking layer and color filters. The color filters are arranged according to the color of light emitted respectively from the light-emitting diodes of the display layer 200.

The cover window 700 is disposed on the anti-reflection layer 600. The cover window 700 protects layers covered by the cover window 700. The cover window 700 is separately formed and attached to the anti-reflection layer 600 by the adhesive layer OCA disposed between the cover window 700 and the anti-reflection layer 600. The adhesive layer OCA may be, for example, an optically transparent adhesive. However, in an embodiment, the cover window 700 is directly disposed on the anti-reflection layer 600.

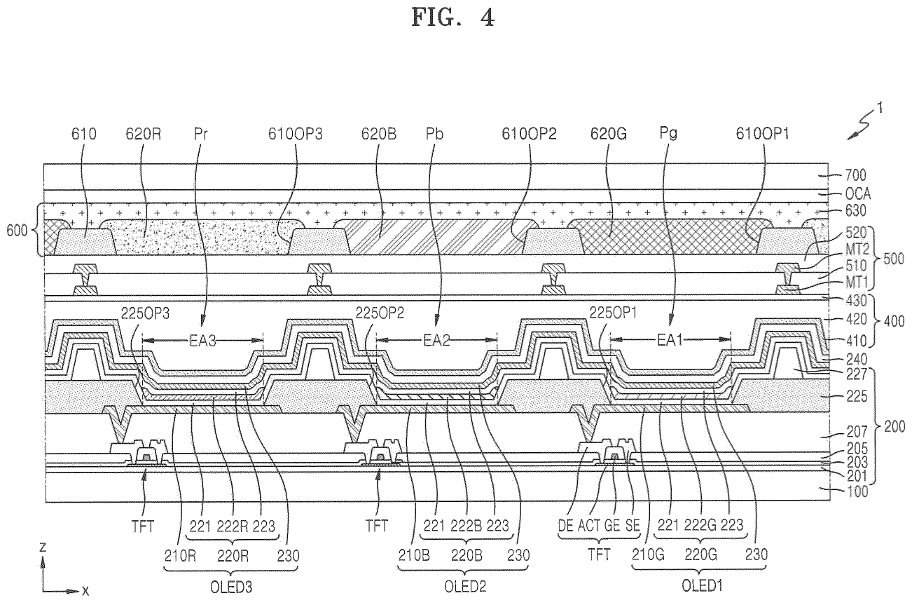

FIG. 4 is a schematic cross-sectional view of the display apparatus 1 according to an embodiment.

Referring to FIG. 4, in an embodiment, the display apparatus 1 includes the substrate 100, the display layer 200, the encapsulation layer 400, the touch sensor layer 500, the anti-reflection layer 600, the adhesive layer OCA, and the cover window 700.

The display apparatus 1 includes the plurality of sub-pixels arranged in the display area DA (see FIG. 1). Each of the plurality of sub-pixels emits one of red, green, or blue light. The plurality of sub-pixels include sub-pixels that emit light of different colors from each other, such as a first-color sub-pixel, a second-color sub-pixel, and a third-color sub-pixel. A plurality of each of the first-color sub-pixels, the second-color sub-pixels, and the third-color sub-pixels are provided. In an embodiment, the first-color sub-pixel is a green sub-pixel Pg that emits green light, the second-color sub-pixel is a blue sub-pixel Pb that emits blue light, and the third-color sub-pixel is a red sub-pixel Pr that emits red light.

The display layer 200 is disposed on the substrate 100. The display layer 200 includes a sub-pixel circuit layer and a light-emitting diode layer. The sub-pixel circuit layer includes thin-film transistors TFT, a buffer layer 201, a gate insulating layer 203, an interlayer insulating layer 205, and a planarization layer 207, which are insulating layers.

The buffer layer 201 is disposed on the substrate 100, reduces or blocks penetration of foreign materials, moisture, or external air from below the substrate 100, and provides a flat surface on the substrate 100. The buffer layer 201 includes at least one of an inorganic material, an organic material, or an organic/inorganic composite material, and may include a single layer or multiple layers that include an inorganic material and an organic material, where the inorganic material includes oxide or nitride. A barrier layer that blocks penetration of external air may be further disposed between the substrate 100 and the buffer layer 201. The buffer layer 201 includes at least one of silicon oxide or silicon nitride.

The thin-film transistor TFT is disposed on the buffer layer 201. The thin-film transistor TFT includes a semiconductor layer ACT, a gate electrode GE, a source electrode SE, and a drain electrode DE. The thin-film transistor TFT is connected to an organic light-emitting diode and drives the organic light-emitting diode.

The semiconductor layer ACT is disposed on the buffer layer 201. The semiconductor layer ACT includes one of polycrystalline silicon or amorphous silicon. In an embodiment, the semiconductor layer ACT includes an oxide of at least one of indium (In), gallium (Ga), tin (Sn), zirconium (Zr), vanadium (V), hafnium (Hf), cadmium (Cd), germanium (Ge), chromium (Cr), titanium (Ti) or zinc (Zn). The semiconductor layer ACT includes a channel region, a source region, and a drain region, and the source region and the drain region are doped with impurities.

The gate electrode GE, the source electrode SE, and the drain electrode DE each include various conductive materials. In an embodiment, the gate electrode GE includes at least one of molybdenum (Mo), aluminum (Al), copper (Cu), or titanium (Ti). For example, the gate electrode GE includes one of a single Mo layer or a three-layered structure that includes a Mo layer, an Al layer, and a Mo layer. In an embodiment, the source electrode SE and the drain electrode DE each include at least one of cupper (Cu), titanium (Ti), or aluminum (λ1). For example, the source electrode SE and the drain electrode DE each include a three-layered structure of a Ti layer, an Al layer, and a Ti layer.

To insulate the semiconductor layer ACT from the gate electrode GE, the gate insulating layer 203 is disposed on the buffer layer 201 and between the semiconductor layer ACT and the gate electrode GE. The interlayer insulating layer 205 is disposed on gate insulating layer 203 and the gate electrode GE, and the source electrode SE and the drain electrode DE is disposed on the interlayer insulating layer 205.

The gate insulating layer 203 and the interlayer insulating layer 205 each include an inorganic material such as at least one of silicon oxide, silicon nitride, and/or silicon oxynitride. The gate insulating layer 203 and the interlayer insulating layer 205 are each be formed by, for example, chemical vapor deposition (CVD) or atomic layer deposition (ALD).

The planarization layer 207 is disposed on the interlayer insulating layer 205 and the thin-film transistor TFT. To provide a flat upper surface, the planarization layer 207 is formed and then chemical mechanical polishing is performed on the upper surface of the planarization layer 207. The planarization layer 207 includes a general-purpose polymer such as at least one of a photosensitive polyimide, a polyimide, a polycarbonate (PC), benzocyclobutene (BCB), a polyimide, hexamethyldisiloxane (HMDSO), polymethylmethacrylate (PMMA) or polystyrene (PS), polymer derivatives that have a phenol-based group, an acryl-based polymer, an imide-based polymer, an aryl ether-based polymer, an amide-based polymer, a fluorine-based polymer, a p-xylene-based polymer, or a vinyl alcohol-based polymer. Although FIG. 4 shows that the planarization layer 207 is a single layer, the planarization layer 207 is a multi-layer structure in another embodiment. Sub-pixel electrodes of first to third organic light-emitting diodes OLED1, OLED2, and OLED3 are electrically connected to the thin-film transistors TFT through contact holes in the planarization layer 207.

The light-emitting diode layer is disposed on the sub-pixel circuit layer. In an embodiment, the light-emitting diode layer includes the first to third organic light-emitting diodes OLED1, OLED2, and OLED3, a bank layer 225, and a spacer 227.

The first organic light-emitting diode OLED1, the second organic light-emitting diode OLED2, and the third organic light-emitting diode OLED3 are disposed on the sub-pixel circuit layer. The first organic light-emitting diode OLED1 includes a stack structure of a sub-pixel electrode 210G, an intermediate layer 220G that includes a first common layer 221, an emission layer 222G, and a second common layer 223, and an opposite electrode 230. The second organic light-emitting diode OLED2 includes a stack structure of a sub-pixel electrode 210B, an intermediate layer 220B that includes the first common layer 221, an emission layer 222B, and the second common layer 223, and the opposite electrode 230. The third organic light-emitting diode OLED3 includes a stack structure of a sub-pixel electrode 210R, an intermediate layer 220R that includes the first common layer 221, an emission layer 222R, and the second common layer 223, and the opposite electrode 230.

The sub-pixel electrodes 210G, 210B, and 210R are disposed on the planarization layer 207. The sub-pixel electrodes 210G, 210B, and 210R are spaced apart from each other.

In an embodiment, the sub-pixel electrodes 210G, 210B, and 210R are reflective electrodes. The sub-pixel electrodes 210G, 210B, and 210R include a reflective layer and a transparent or semi-transparent conductive layer on the reflective layer, where the reflective layer includes at least one of silver (Ag), magnesium (Mg), aluminum (Al), platinum (Pt), palladium (Pd), gold (Au), nickel (Ni), neodymium (Nd), iridium (Ir), chrome (Cr), or a compound thereof. The transparent or semi-transparent conductive layer includes at least one of indium tin oxide (ITO), indium zinc oxide (IZO), zinc oxide (ZnO), indium oxide (In₂O₃), indium gallium oxide (IGO), or aluminum zinc oxide (AZO).

The bank layer 225 is disposed on the sub-pixel electrodes 210G, 210B, and 210R. The bank layer 225 overlaps the sub-pixel electrodes 210G, 210B, and 210R and includes first to third lower openings 225OP1, 225OP2, and 225OP3 that respectively expose central portions of the sub-pixel electrodes 210G, 210B, and 210R. The bank layer 225 covers the edges of the sub-pixel electrodes 210G, 210B, and 210R and prevents arcs, etc., from occurring at the edges of the sub-pixel electrodes 210G, 210B, and 210R by increasing a distance between the edges of the sub-pixel electrodes 210G, 210B, and 210R and the opposite electrode 230.

The first to third lower openings 225OP1, 225OP2, and 225OP3 of the bank layer 225 respectively define first to third emission areas EA1, EA2, and EA3 of the first to third organic light-emitting diode OLED1, OLED2, and OLED3 in the respective sub-pixels. As shown in FIG. 4, the bank layer 225 includes the first lower opening 225OP1 that defines the first emission area EA1 of the first organic light-emitting diode OLED1 of the first-color sub-pixel. In addition, the bank layer 225 includes the second lower opening 225OP2 that defines the second emission area EA2 of the second organic light-emitting diode OLED2 of the second-color sub-pixel, and the bank layer 225 includes the third lower opening 225OP3 that defines the third emission area EA3 of the third organic light-emitting diode OLED3 of the third-color sub-pixel.

The bank layer 225 includes an organic insulating material. In an embodiment, the bank layer 225 includes an inorganic insulating material such as silicon nitride or silicon oxide. In an embodiment, the bank layer 225 includes an organic insulating material and an inorganic insulating material.

In an embodiment, the bank layer 225 includes a light-blocking material. For example, the light-blocking material of the bank layer 225 is black. The light-blocking material includes at least one of carbon black, carbon nanotubes, a resin or paste that includes black dye, metal particles, such as nickel, aluminum, molybdenum, or an alloy thereof, metal oxide particles or metal nitride particles. When the bank layer 225 includes a light-blocking material, external light reflection by metal structures below the bank layer 225 is reduced.

The spacer 227 is disposed on the bank layer 225. The spacer 227 includes an organic insulating material such as polyimide. In an embodiment, the spacer 227 includes an inorganic insulating material such as one of silicon nitride or silicon oxide, or includes an organic insulating material and an inorganic insulating material. In an embodiment, the spacer 227 includes a light-blocking material that includes a material that differs from that of the bank layer 225. The spacer 227 and the bank layer 225 are respectively formed in separate processes.

In an embodiment, the spacer 227 includes the same material as the bank layer 225. For example, the bank layer 225 and the spacer 227 are simultaneously formed during a mask process that uses a half-tone mask.

The intermediate layer is disposed on the sub-pixel electrodes 210G, 210B, and 210R and the bank layer 225. As described above, the intermediate layer includes the first common layer 221, the emission layer, and the second common layer 223.

The emission layers 222G, 222B, and 222R are disposed inside the first to third lower openings 225OP1, 225OP2, and 225OP3 of the bank layer 225. The emission layers 222G, 222B, and 222R include an organic material that includes a fluorescent or phosphorous material that emits one of green, blue, or red light. The organic material includes a low molecular weight organic material or a polymer organic material.

The first common layer 221 and the second common layer 223 are respectively disposed under and over the emission layer. The first common layer 221 includes, for example, a hole transport layer (HTL), or includes an HTL and a hole injection layer (HIL). The second common layer 223 includes, for example, an electron transport layer (ETL), or includes an ETL and an electron injection layer (EIL). In an embodiment, the second common layer 223 is omitted.

The emission layer for each sub-pixel respectively corresponds to the first to third lower openings 225OP1, 225OP2, and 225OP3 of the bank layer 225. However, the first common layer 221 and the second common layer 223 may each be integrally formed to entirely cover the substrate 100. For example, the first common layer 221 and the second common layer 223 are each formed as one body to cover the display area DA of the substrate 100.

The opposite electrode 230 is a cathode which is an electron injection electrode. The opposite electrode 230 includes a conductive material that has a low work function. For example, the opposite electrode 230 includes a (semi) transparent layer that includes at least one of silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or an alloy thereof. In an embodiment, the opposite electrode 230 further includes a layer that includes ITO, IZO, ZnO, or In₂O₃ on the (semi) transparent layer.

In an embodiment, a capping layer 240 is further disposed on the display layer 200. The capping layer 240 is disposed on the first to third organic light-emitting diodes OLED1, OLED2, and OLED3. In an embodiment, the capping layer 240 improves a light-emission efficiency of the first to third organic light-emitting diodes OLED1, OLED2, and OLED3 due to a principle of constructive interference.

The capping layer 240 may be an organic capping layer that includes an organic material, an inorganic capping layer that includes an inorganic material, or a composite capping layer that includes an organic material and an inorganic material. For example, the capping layer 240 is one of a carbocyclic compound, a heterocyclic compound, an amine group-containing compound, porphine derivatives, phthalocyanine derivatives, naphthalocyanine derivatives, alkali metal complexes, alkali earth metal complexes, or an arbitrary combination thereof. Carbocyclic compounds, heterocyclic compounds, and amine group-containing compounds may optionally be substituted with substituents that include at least one of O, N, S, Se, Si, F, Cl, Br, I, or an arbitrary combination thereof.

The encapsulation layer 400 is disposed on the capping layer 240. The encapsulation layer 400 includes at least one inorganic encapsulation layer and at least one organic encapsulation layer. For example, as shown in FIG. 4, the encapsulation layer 400 includes a first inorganic encapsulation layer 410, an organic encapsulation layer 420, and a second inorganic encapsulation layer 430 that are sequentially stacked.

The first inorganic encapsulation layer 410 and the second inorganic encapsulation layer 430 each include an inorganic insulating material such as at least one of silicon oxide, silicon nitride, silicon oxynitride, aluminum oxide, titanium oxide, tantalum oxide, hafnium oxide, or zinc oxide. The first inorganic encapsulation layer 410 and the second inorganic encapsulation layer 430 may each have a single-layered structure or a multi-layered structure that includes the inorganic insulating material.

The organic encapsulation layer 420 alleviates internal stress of the first inorganic encapsulation layer 410 and/or the second inorganic encapsulation layer 430. The organic encapsulation layer 420 includes a polymer-based material. For example, the organic encapsulation layer 420 includes at least one of polyethylene terephthalate, polyethylene naphthalate, polycarbonate, polyimide, polyethylene sulfonate, polyoxymethylene, polyarylate, hexamethyldisiloxane, an acryl-based resin such as polymethylmethacrylate or poly acrylic acid, etc., or an arbitrary combination thereof.

The encapsulation layer 400 has a multi-layered structure of the first inorganic encapsulation layer 410, the organic encapsulation layer 420, and the second inorganic encapsulation layer 430. For example, even though cracks can occur in the encapsulation layer 400, the cracks do not propagate between the first inorganic encapsulation layer 410 and the organic encapsulation layer 420, or between the organic encapsulation layer 420 and the second inorganic encapsulation layer 430. The encapsulation layer 400 prevents or reduces external moisture, oxygen, etc., from penetrating into the display area DA.

The touch sensor layer 500 is disposed on the encapsulation layer 400. The touch sensor layer 500 includes a first touch electrode MT1, a first touch insulating layer 510, a second touch electrode MT2, and a second touch insulating layer 520. The first touch electrode MT1 is directly disposed on the encapsulation layer 400. For example, the first touch electrode MT1 is directly disposed on the second inorganic encapsulation layer 430 of the encapsulation layer 400. However, embodiments are not necessarily limited thereto.

In an embodiment, the touch sensor layer 500 includes an insulating layer between the first touch electrode MT1 and the encapsulation layer 400. For example, the insulating layer is disposed on the second inorganic encapsulation layer 430 of the encapsulation layer 400 and planarizes a surface on which the first touch electrode MT1, etc., is disposed. The insulating layer includes an inorganic insulating material such as one of silicon oxide, silicon nitride, or silicon oxynitride. In an embodiment, the insulating layer includes an organic insulating material.

The first touch insulating layer 510 is disposed on the second inorganic encapsulation layer 430 and the first touch electrode MT1. The first touch insulating layer 510 includes an inorganic material or an organic material. When the first touch insulating layer 510 includes an inorganic material, the first touch insulating layer 510 includes at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride. When the first touch insulating layer 510 includes an organic material, the first touch insulating layer 510 includes at least one of an acryl-based resin, a methacryl-based resin, a polyisoprene, a vinyl-based resin, an epoxy-based resin, a urethane-based resin, a cellulose resin, or a perylene-based resin.

The second touch electrode MT2 is disposed on the first touch insulating layer 510. The second touch electrode MT2 is a sensor that senses a user's touch input. The first touch electrode MT1 is a connector that connects the second touch electrode MT2 patterned in one direction. In an embodiment, both the first touch electrode MT1 and the second touch electrode MT2 serve as sensors. For example, the first touch electrode MT1 is electrically connected to the second touch electrode MT2 through a contact hole. When both the first touch electrode MT1 and the second touch electrode MT2 serve as sensors, a resistance of a touch electrode is reduced and a user's touch input can be swiftly sensed.

In an embodiment, the first touch electrode MT1 and the second touch electrode MT2 have a structure through which light emitted from the organic light-emitting diode can pass, such as a mesh structure. For example, the first touch electrode MT1 and the second touch electrode MT2 do not overlap the emission area EA of the organic light-emitting diode.

The first touch electrode MT1 and the second touch electrode MT2 each include one of a metal layer or a transparent conductive layer. The metal layer includes at least one of molybdenum (Mo), silver (Ag), titanium (Ti), copper (Cu), aluminum (Al), or an alloy thereof. The transparent conductive layer includes a transparent conductive oxide such as at least one of indium tin oxide (ITO), zinc oxide (ZnO), or indium tin zinc oxide (ITZO), a conductive polymer such as poly(3,4-ethylenedioxythiophene) (PEDOT), a metal nanowire, a carbon nanotube, or graphene.

The second touch insulating layer 520 is disposed on the first touch insulating layer 510 and the second touch electrode MT2. The second touch insulating layer 520 includes an inorganic material or an organic material. When the second touch insulating layer 520 includes an inorganic material, the second touch insulating layer 520 includes at least one of silicon nitride, aluminum nitride, zirconium nitride, titanium nitride, hafnium nitride, tantalum nitride, silicon oxide, aluminum oxide, titanium oxide, tin oxide, cerium oxide, or silicon oxynitride. When the second touch insulating layer 520 includes an organic material, the second touch insulating layer 520 includes at least one of an acryl-based resin, a methacryl-based resin, a polyisoprene, a vinyl-based resin, an epoxy-based resin, a urethane-based resin, a cellulose resin, or a perylene-based resin.

In an embodiment, the touch sensor layer 500 includes the first touch electrode MT1, the first touch insulating layer 510, and the second touch electrode MT2, and but not the second touch insulating layer 520. For example, the anti-reflection layer 600 has a structure that covers the second touch electrode MT2.

The anti-reflection layer 600 is disposed on the touch sensor layer 500.

Referring to FIG. 4, the anti-reflection layer 600 includes a light-blocking layer 610, a plurality of color filters, and an overcoat layer 630. In an embodiment, the anti-reflection layer 600 includes first to third color filters 620G, 620B, and 620R of different colors that respectively correspond to the first to third organic light-emitting diodes OLED1, OLED2, and OLED3. A plurality of each of the first to third color filters 620G, 620B, and 620R are provided.

The light-blocking layer 610 includes first to third upper openings 610OP1, 610OP2, and 610OP3 that respectively correspond to the first-color to third-color sub-pixels. The light-blocking layer 610 includes the first upper opening 610OP1 that corresponds to the first emission area EA1, the second upper opening 610OP2 that corresponds to the second emission area EA2, and the third upper opening 610OP3 that corresponds to the third emission area EA3. Light emitted from the first to third organic light-emitting diodes OLED1, OLED2, and OLED3 is emitted through the first to third upper openings 610OP1, 610OP2, and 610OP3 of the light-blocking layer 610, respectively.

The first upper opening 610OP1 of the light-blocking layer 610 overlaps the first lower opening 225OP1 of the bank layer 225, the second upper opening 610OP2 overlaps the second lower opening 225OP2, and the third upper opening 610OP3 overlaps the third lower opening 225OP3.

In the present specification, the width (or the size) of each sub-pixel denotes the width (or the size) of the emission area of the organic light-emitting diode that implements each sub-pixel, and the width (or the size) of the emission area may be defined by the width (or the size) of the lower opening of the bank layer 225.

In an embodiment, the width (or the size) of each of the first to third upper openings 610OP1, 610OP2, and 610OP3 of the light-blocking layer 610 is greater than the width (or the size) of the corresponding sub-pixel of the first-color to third-color sub-pixels. For example, the widths (or the sizes) of the first to third upper openings 610OP1, 610OP2, and 610OP3 of the light-blocking layer 610 are greater than the widths (or the sizes) of the respective corresponding first to third lower openings 225OP1, 225OP2, and 225OP3 of the bank layer 225.

In an embodiment, the width (or the size) of each of the first to third upper openings 610OP1, 610OP2, and 610OP3 of the light-blocking layer 610 is substantially the same as the width (or the size) of the corresponding sub-pixel of the first-color to third-color sub-pixels. For example, the widths (or the sizes) of the first to third upper openings 610OP1, 610OP2, and 610OP3 of the light-blocking layer 610 are substantially the same as the widths (or the sizes) of the respective corresponding first to third lower openings 225OP1, 225OP2, and 225OP3 of the bank layer 225.

The light-blocking layer 610 includes an organic insulating material. In an embodiment, the light-blocking layer 610 includes an inorganic insulating material such as silicon nitride or silicon oxide. In an embodiment, the light-blocking layer 610 includes an organic insulating material and an inorganic insulating material.

In an embodiment, the light-blocking layer 610 includes a light-blocking material. For example, the light-blocking material of the light-blocking layer 610 is black. The light-blocking material includes at least one of carbon black, carbon nanotubes, a resin or paste that includes a black dye, metal particles, such as nickel, aluminum, molybdenum, or an alloy thereof, metal oxide particles or metal nitride particles. Because the light-blocking layer 610 includes a light-blocking material, external light reflection by metal structures disposed below the light-blocking layer 610 is reduced.

The first to third color filters 620G, 620B, and 620R are respectively arranged in the first to third upper openings 610OP1, 610OP2, and 610OP3 of the light-blocking layer 610. The first to third color filters 620G, 620B, and 620R have colors that correspond to light emitted from first to third emission areas EA1, EA2, and EA3, respectively. In an embodiment, when the first emission area EA1 emits green light, the first color filter 620G is a green color filter, when the second emission area EA2 emits blue light, the second color filter 620B is a blue color filter, and when the third emission area EA3 emits red light, the third color filter 620R is a red color filter.

The anti-reflection layer 600 further includes the overcoat layer 630. The overcoat layer 630 is disposed on the light-blocking layer 610 and/or the first to third color filters 620G, 620B, and 630R. The overcoat layer 630 planarizes the upper surface of the light-blocking layer 610 and/or the first to third color filters 620G, 620B, and 630R. The overcoat layer 630 is a colorless light-transmissive layer that allows substantially all visible light frequencies to pass therethrough. The overcoat layer 630 includes a colorless light-transmissive organic material such as an acryl-based resin.

The cover window 700 is disposed over the overcoat layer 630 with the adhesive layer OCA therebetween.

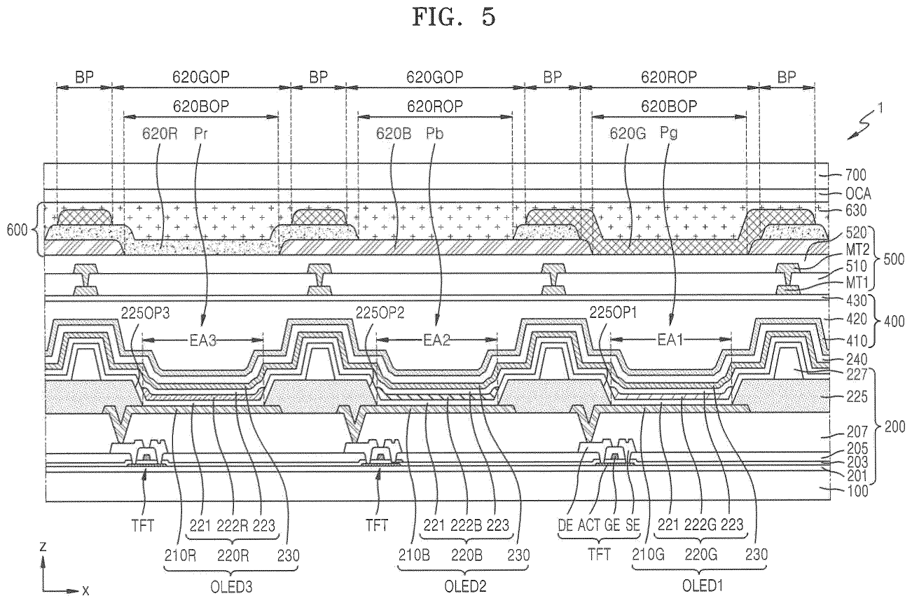

FIG. 5 is a schematic cross-sectional view of a display apparatus according to an embodiment. FIG. 5 shows a modified embodiment of the anti-reflection layer 600 of FIG. 4. Hereinafter, differences are mainly described.

Referring to FIG. 5, in an embodiment, the anti-reflection layer 600 includes only the plurality of color filters without the light-blocking layer 610 (see FIG. 4).

In an embodiment, the second color filter 620B, the third color filter 620R, and the first color filter 620G are sequentially stacked in a direction (a +z direction) away from the substrate 100.

The second color filter 620B passes mostly blue light and block most of red light or green light. The second color filter 620B includes second openings 620BOP that correspond to the first emission area EA1 and the third emission area EA3. The second color filter 620B includes the second openings 620BOP such that red light and green light emitted from the first emission area EA1 and the third emission area EA3 are not blocked. Most of the blue light emitted from the second emission area EA2 passes through and is emitted from the second color filter 620B.

The third color filter 620R passes mostly red light and blocks most of blue light or green light. The third color filter 620R fills some of the second openings 620BOP of the second color filter 620B that correspond to the third emission area EA3, and is disposed on the second color filter 620B between emission areas. The third color filter 620R includes third openings 620ROP that correspond to the first emission area EA1 and the second emission area EA2. The third color filter 620R includes the third openings 620ROP such that green light and blue light emitted from the first emission area EA1 and the second emission area EA2 are not blocked. Most of the red light emitted from the third emission area EA3 passes through and is emitted from the third color filter 620R.

The first color filter 620G passes mostly green light and blocks most of red light or blue light. The first color filter 620G fills some of the second openings 620BOP of the second color filter 620B and some of the third openings 620ROP of the third color filter 620R that correspond to the first emission area EA1, and is disposed on the third color filter 620R between the emission areas. The first color filter 620G includes first openings 620GOP that correspond to the second emission area EA2 and the third emission area EA3. The first color filter 620G includes the first openings 620GOP such that the blue light and red light emitted from the second emission area EA2 and the third emission area EA3 are not blocked. Most of green light emitted from the first emission area EA1 may pass through and is emitted from the first color filter 620G.

The anti-reflection layer 600 includes light-blocking portions BP between the emission areas. For example, light-blocking portions BP are disposed in portions that correspond to a space between the first to third emission areas EA1, EA2, and EA3, or a space between the sub-pixel electrodes 210G, 210B, and 210R. The light-blocking portions BP include the first to third color filters 620G, 620B, and 620R that are sequentially stacked. The light-blocking portions BP can block light even without the light-blocking layer 610 (see FIG. 4) that includes a black light-blocking material. In addition, external light reflection of the display apparatus can be reduced.

In an embodiment, the width (the size) of the third opening 620ROP of the third color filter 620R that overlaps the first emission area EA1 of the first-color sub-pixel is greater than the width (the size) of the second opening 620BOP of the second color filter 620B. The width (the size) of the first opening 620GOP of the first color filter 620G that overlaps the second emission area EA2 of the second-color sub-pixel is greater than the width (the size) of the third opening 620ROP of the third color filter 620R. The width (the size) of the first opening 620GOP of the first color filter 620G that overlaps the third emission area EA3 of the third-color sub-pixel is greater than the width (the size) of the second opening 620BOP of the second color filter 620B.

Hereinafter, although a description assumes that a display apparatus includes the anti-reflection layer 600 of FIG. 4, the same structure also applies to a display apparatus that includes the anti-reflection layer 600 of FIG. 5.

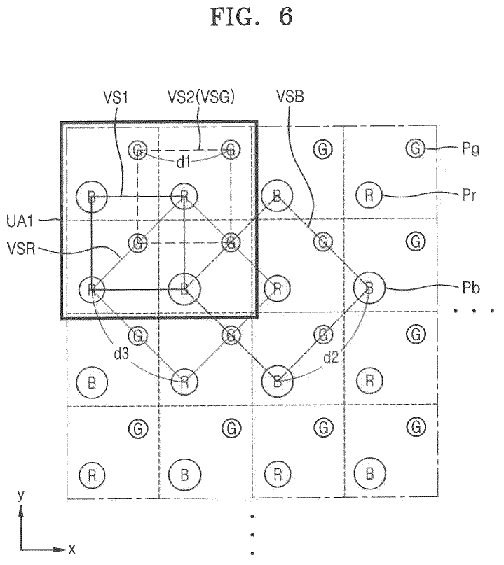

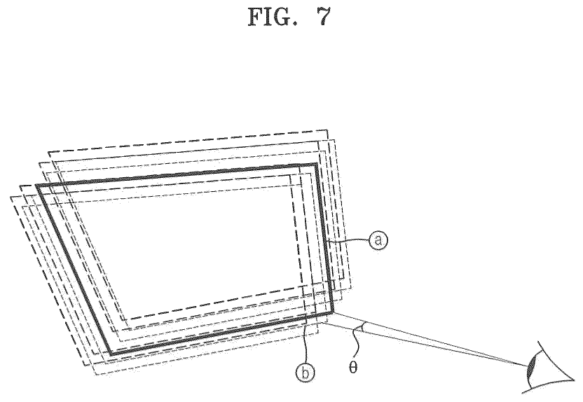

FIG. 6 is a plan view of a configuration of sub-pixels of a portion of a display apparatus according to an embodiment, and FIG. 7 illustrates a multiple image phenomenon caused by external light reflection and diffraction of a display apparatus.

Referring to FIG. 6, in an embodiment, the plurality of sub-pixels of the display apparatus include the first-color sub-pixel, the second-color sub-pixel, and the third-color sub-pixel. In an embodiment, the first-color sub-pixel is a green sub-pixel Pg, the second-color sub-pixel is a blue sub-pixel Pb, and the third-color sub-pixel is a red sub-pixel Pr. Hereinafter, description is made on the assumption that the first-color sub-pixel is a green sub-pixel Pg, the second-color sub-pixel is a blue sub-pixel Pb, and the third-color sub-pixel is a red sub-pixel Pr.

The red sub-pixels Pr, the blue sub-pixels Pb, and the green sub-pixels Pg have a repeated configuration structure. In an embodiment, the red sub-pixels Pr and the blue sub-pixels Pb are arranged on vertices of a virtual rectangle VS1 with one green sub-pixel Pg as a center point. The red sub-pixels Pr are respectively arranged on opposite vertices in a diagonal direction of the virtual rectangle VS1 with the green sub-pixel Pg therebetween, and the blue sub-pixels Pb are respectively arranged on opposite vertices in a diagonal direction of the virtual rectangle VS1 with the green sub-pixel Pg therebetween. In addition, the green sub-pixels Pg are respectively arranged on vertices of a virtual rectangle VS2 with a sub-pixel, either a blue sub-pixel Pb or a red sub-pixel Pr, as a center point, where the sub-pixel, either a blue sub-pixel Pb or a red sub-pixel Pr, is arranged on one vertex of the virtual rectangle VS1. In an embodiment, the virtual rectangles VS1 and VS2 are squares.

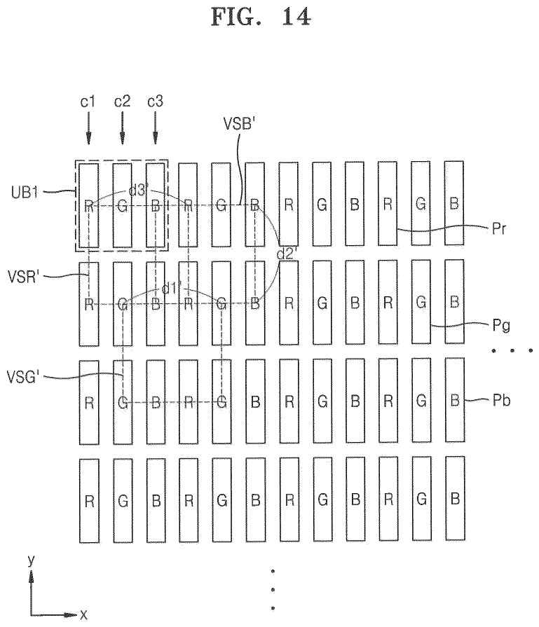

For example, the red sub-pixel Pr, blue sub-pixel Pb, and green sub-pixel Pg are arranged in a PENTILE™ structure, such as a diamond pentile structure. However, embodiments are not necessarily limited thereto. For example, as shown in FIG. 14 described below, the red sub-pixel Pr, blue sub-pixel Pb, and green sub-pixel Pg are arranged in a stripe structure.

The red sub-pixel Pr, the blue sub-pixel Pb, and the green sub-pixel Pg each have a circular shape. However, embodiments are not necessarily limited thereto. In an embodiment, the red sub-pixel Pr, the blue sub-pixel Pb, and the green sub-pixel Pg have an elliptical shape or a polygonal shape. The polygonal shape may include a shape that has round vertices.

The red sub-pixel Pr, the blue sub-pixel Pb, and the green sub-pixel Pg have different sizes (or widths) from each other. For example, the size (or width) of the green sub-pixel Pg is less than the size of the red sub-pixel Pr and the blue sub-pixel Pb. The size (or width) of the blue sub-pixel Pb is greater than the size (or width) of the red sub-pixel Pr. In an embodiment, the sizes of the red sub-pixel Pr, the blue sub-pixel Pb, and the green sub-pixel Pg are substantially the same. However, various modifications may be made.

The sub-pixels of the display apparatus have a repeated configuration structure of a sub-pixel pattern unit block UA1. For example, the configuration of the red sub-pixels Pr, the blue sub-pixels Pb, and the green sub-pixels Pg corresponds to a repeated configuration of the preset sub-pixel pattern unit block UA1. In an embodiment, the sub-pixel pattern unit block is a virtual unit block that has a preset area and includes the red sub-pixel Pr, the blue sub-pixel Pb, and the green sub-pixel Pg. The sub-pixel pattern unit block corresponds to a minimum repeated unit of a configuration pattern of the sub-pixels in the display apparatus. For example, the sub-pixel pattern unit block UA1 is a square.

In an embodiment, the sub-pixel pattern unit block UA1 includes the red sub-pixel Pr, the blue sub-pixel Pb, and the green sub-pixel Pg. A sum of the number of the red sub-pixels Pr and blue sub-pixels Pb in the sub-pixel pattern unit block UA1 is equal to the number of green sub-pixels Pg. For example, a number ratio of green sub-pixels Pg, blue sub-pixels Pb, and red sub-pixels Pr in the sub-pixel pattern unit block UA1 is 2:1:1. FIG. 6 shows that the sub-pixel pattern unit block UA1 includes four green sub-pixels Pg, two blue sub-pixels Pb, and two red sub-pixels Pr.

In the sub-pixel configuration structure of FIG. 6, green sub-pixels Pg adjacent to each other are respectively arranged on vertices of a virtual rectangle VSG with a red sub-pixel Pr or a blue sub-pixel Pb as a center point. Blue sub-pixels Pb adjacent to each other are respectively arranged on vertices of a virtual rectangle VSB with a red sub-pixel Pr as a center point. Red sub-pixels Pr adjacent to each other are respectively arranged on vertices of a virtual rectangle VSR with a blue sub-pixel Pb as a center point. Two green sub-pixels Pg adjacent to each other are arranged in an x direction or a y direction. Two blue sub-pixels Pb adjacent to each other are arranged in a diagonal direction inclined with respect to the x direction or y direction. Two red sub-pixels Pr adjacent to each other are arranged in a diagonal direction inclined with respect to the x direction or y direction. Two blue sub-pixels Pb adjacent to each other are arranged in a diagonal direction inclined with respect to the x direction or y direction. Two blue sub-pixels Pb adjacent to each other are arranged in a direction inclined at 45° with respect to the x direction or y direction. Two red sub-pixels Pr adjacent to each other are arranged in a direction inclined at 45° with respect to the x direction or y direction.

In an embodiment, a first distance d1 between two adjacent green sub-pixels Pg is less than a second distance d2 between two adjacent blue sub-pixels Pb. The first distance d1 between two adjacent green sub-pixels Pg is less than a third distance d3 between two adjacent red sub-pixels Pr. The second distance d2 between two adjacent blue sub-pixels Pb is equal to the third distance d3 between two adjacent red sub-pixels Pr. For example, the first distance d1 between two adjacent green sub-pixels Pg is 1/\sqrt{2} times the second distance d2 or 1/\sqrt{2} times the third distance d3.

Referring to FIG. 4, the display apparatus 1 according to an embodiment includes the light-blocking layer 610 and/or the anti-reflection layer 600 that includes the first to third color filters 620G, 620B, and 620R. The display apparatus 1 that includes the anti-reflection layer 600 has a high light efficiency as compared to a display apparatus that includes a polarizing film disposed on the front surface of the substrate 100. However, external light reflection caused by each sub-pixel, such as a sub-pixel electrode or an opposite electrode of each sub-pixel, can increase. In addition, interference patterns that occur due to diffraction of light reflected by each sub-pixel can increase.

For example, FIG. 7 schematically shows images formed by light reflected or diffracted in the display apparatus. Referring to FIG. 7, in an embodiment, blurry diffraction images are shifted vertically and/or horizontally around a clear regular reflection image \textcircled{a} and appear around the regular reflection image \textcircled{a}, which is called a multiple image. Such multiple image is a type of interference pattern generated by diffraction and interference of light reflected from each sub-pixel, and an angle at which the regular reflection image \textcircled{a} and a first diffraction image \textcircled{a} are separated in the vertical and/or horizontal directions is called a ‘separation angle’.

Such interference patterns are caused by light reflected from sub-pixels of the same color, such as light reflected from the green sub-pixels Pg, light reflected from the red sub-pixels Pr, or light reflected from the blue sub-pixels Pb. Sub-pixels of the same color that generate the interference pattern are arranged adjacent to each other. The interference pattern can change depending on the wavelength of light reflected from each sub-pixel. In addition, the interference pattern can change depending on the shape of a sub-pixel, an interval between sub-pixels, and a configuration structure of the sub-pixels. Multiple images respectively formed by light reflected from the green sub-pixel Pg, the blue sub-pixel Pb, and the red sub-pixel Pr that have different wavelengths have different separation angles from each other.

In the sub-pixel configuration structure of FIG. 6, the first distance d1 between adjacent green sub-pixels Pg is less than the second distance d2 between adjacent blue sub-pixels Pb and the third distance d3 between adjacent red sub-pixels Pr. Adjacent green sub-pixels Pg are arranged in the x direction and y direction. However, adjacent blue sub-pixels Pb and adjacent red sub-pixels Pr are arranged in a diagonal direction. As a result, a separation angle of multiple images formed by light reflected from a green sub-pixel Pg is greater than a separation angle of multiple images formed by light reflected from a red sub-pixel Pr and a separation angle of multiple images formed by light reflected from a blue sub-pixel Pb. For example, in the sub-pixel configuration structure of FIG. 6, a separation angle of multiple images formed by light reflected from a green sub-pixel Pg is about 1.5 times to about 2.5 times a separation angle of multiple images formed by light reflected from a red sub-pixel Pr and a separation angle of multiple images formed by light reflected from a blue sub-pixel Pb. For, when a difference in the separation angle of the multiple images formed by the light reflected from the green sub-pixel Pg, the blue sub-pixel Pb, and the red sub-pixel Pr is large, color separation can occur and visibility of the multiple images can increase.

However, because a display apparatus according an embodiment includes a phase difference pattern structure that allows light reflected from adjacent green sub-pixels Pg to have a phase difference that does not cancel or constructively interfere with each other, a separation angle of multiple images formed by light reflected from the green sub-pixels Pg is reduced. Accordingly, because a difference in the separation angle of multiple images respectively formed by light reflected from the green sub-pixels Pg, light reflected from the blue sub-pixels Pb, and light reflected from the red sub-pixels Pr is reduced, color separation is reduced and visibility of the multiple images is reduced.

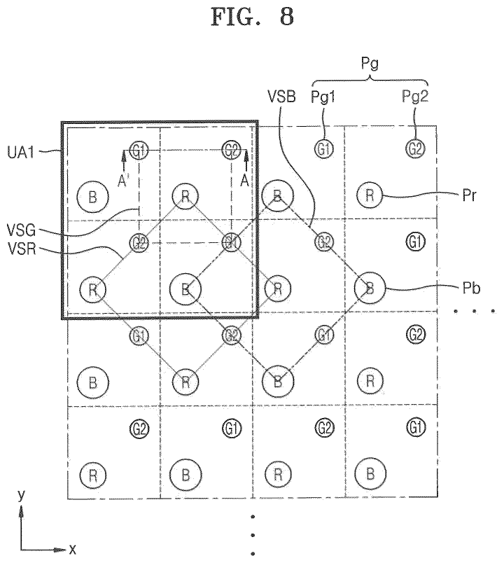

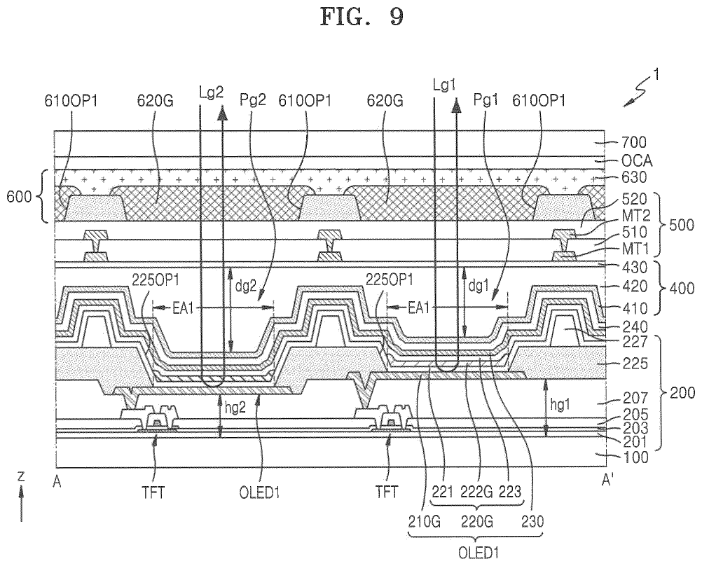

FIG. 8 is a plan view of sub-pixels of the display apparatus 1 according to an embodiment. FIG. 9 is a schematic cross-sectional view of a display apparatus according to an embodiment. FIG. 8 shows a phase difference pattern structure based on a sub-pixel configuration structure of FIG. 7. FIG. 9 is a cross-sectional view of a display apparatus, taken along line A-A′ of FIG. 8.

Referring to FIG. 8, in an embodiment, the green sub-pixels Pg of the display apparatus 1 include a first green sub-pixel Pg1 and a second green sub-pixel Pg2. The first green sub-pixel Pg1 and the second green sub-pixel Pg2 that are adjacent to each other have a phase difference that does not cancel and constructively interfere with each other.

A phase pattern structure of FIG. 8 includes a repeated configuration structure of a phase difference pattern unit block. A configuration of the first green sub-pixel Pg1, the second green sub-pixel Pg2, the blue sub-pixels Pb, and the red sub-pixels Pr corresponds to a repeated configuration of a preset phase difference pattern unit block. In an embodiment, a phase difference pattern unit block is a virtual unit block that has a preset area. A phase difference pattern unit block corresponds to a minimum repeated unit of a configuration pattern of the sub-pixels that include sub-pixels of the same color with a phase difference. In an embodiment, a phase difference pattern unit block is the same as a sub-pixel pattern unit block UA1.

In a repeated configuration structure of a phase difference pattern unit block, such as the sub-pixel pattern unit block UA1, the first green sub-pixel Pg1 and the second green sub-pixel Pg2 are respectively arranged on adjacent vertices in a virtual rectangle VSG with the red sub-pixel Pr or the blue sub-pixel Pb as a center point. The first green sub-pixels Pg1 are respectively arranged on a first pair of opposite vertices of the virtual rectangle VSG. The second green sub-pixels Pg2 are respectively arranged on a second pair of opposite vertices of the virtual rectangle VSG. In an embodiment, the first green sub-pixel Pg1 may be denoted as a first-1 color sub-pixel, and the second green sub-pixel Pg2 may be denoted as a first-2 color sub-pixel.

FIG. 9 shows a cross-sectional structure of the first green sub-pixel Pg1 and the second green sub-pixel Pg2 of FIG. 8. Referring to FIG. 9, in an embodiment, each of the first green sub-pixel Pg1 and the second green sub-pixel Pg2 includes the sub-pixel electrode 210G, the intermediate layer 220G, and the opposite electrode 230 that form the first organic light-emitting diode OLED1. Light reflected from each sub-pixel is reflected from a metal layer of each sub-pixel, such as the sub-pixel electrode or the opposite electrode. For example, first green light Lg1 is reflected from the sub-pixel electrode 210G of the first green sub-pixel Pg1. Second green light Lg2 is reflected from the sub-pixel electrode 210G of the second green sub-pixel Pg2.

A vertical distance hg1 from the substrate 100 to the sub-pixel electrode 210G of the first green sub-pixel Pg1 differs from a vertical distance hg2 from the substrate 100 to the sub-pixel electrode 210G of the second green sub-pixel Pg2. For example, a vertical distance hg1 from the substrate 100 to the sub-pixel electrode 210G of the first green sub-pixel Pg1 is greater than a vertical distance hg2 from the substrate 100 to the sub-pixel electrode 210G of the second green sub-pixel Pg2.

In an embodiment, a thickness of a portion of the planarization layer 207 that corresponds to the first green sub-pixel Pg1 differs from a thickness of a portion of the planarization layer 207 that corresponds to the second green sub-pixel Pg2. For example, a thickness of the portion of the planarization layer 207 that corresponds to the first green sub-pixel Pg1 is greater than a thickness of the portion of the planarization layer 207 that corresponds to the second green sub-pixel Pg2.

For example, the height of the sub-pixel electrode 210G of the first green sub-pixel Pg1 with respect to the substrate 100 differs from the height of the sub-pixel electrode 210G of the second green sub-pixel Pg2. For example, the height of the sub-pixel electrode 210G of the first green sub-pixel Pg1 is greater than the height of the sub-pixel electrode 210G of the second green sub-pixel Pg2. Accordingly, travel paths of the first green light Lg1 and the second green light Lg2 reflected from the respective sub-pixel electrodes 210G differ from each other. For example, a travel path of the first green light Lg1 is shorter than a travel path of the second green light Lg2.

Because the height of the sub-pixel electrode 210G of the first green sub-pixel Pg1 with respect to the substrate 100 differs from the height of the sub-pixel electrode 210G of the second green sub-pixel Pg2, the thicknesses of the organic encapsulation layer 420 that cover the respective sub-pixel electrodes 210G differ from each other. Of the travel paths of the first green light Lg1 and the second green light Lg2, the thicknesses of respective portions of the organic encapsulation layer 420 through which the first green light Lg1 and the second green light Lg2 pass differ from each other. The first green light Lg1 and the second green light Lg2 have a phase difference.

For example, when the first green light Lg1 and the second green light Lg2 have the same wavelength λ1 in a vacuum, and the refractive index of the organic encapsulation layer 420 is n0, the first green light Lg1 and the second green light Lg2 have respective phases ϕ1 and ϕ2 as shown in Equations 1 and 2 below, when passing through the organic encapsulation layer 420.

$${ϕ}_{1} = 2 \cdot \frac{2 π}{λ1} n 0 \cdot dg 1 \qquad EQ . ( 1 )$$

$${ϕ}_{2} = 2 \cdot \frac{2 π}{λ1} n 0 \cdot dg 2 \qquad EQ . ( 2 )$$

Here, dg1 is a thickness of a portion of the organic encapsulation layer 420 that corresponds to the first green sub-pixel Pg1, and dg2 is a thickness of a portion of the organic encapsulation layer 420 that corresponds to the second green sub-pixel Pg2. For example, the thickness dg1 of the portion of the organic encapsulation layer 420 that corresponds to the first green sub-pixel Pg1 is less than the thickness dg2 of the portion of the organic encapsulation layer 420 that corresponds to the second green sub-pixel Pg2.

Accordingly, the first green light Lg1 and the second green light Lg2 have a phase difference. For example, the first green light Lg1 and the second green light Lg2 have a phase difference as expressed in Equation 3 below.

$${Δϕ}_{21} = {ϕ}_{2} - {ϕ}_{1} = 2 \cdot \frac{2 π}{λ1} n 0 \cdot Δ dg , ( Δ dg = dg 2 - dg 1 ) \qquad EQ . ( 3 )$$

Here, Δdg is a difference in the thickness of portions of the organic encapsulation layer 420 through which the first green light Lg1 and the second green light Lg2 pass. For example, the difference Δdg in the thickness of portions of the organic encapsulation layer 420 through which the first green light Lg1 and the second green light Lg2 pass corresponds to a difference Δhg between a vertical distance hg1 from the substrate 100 to the sub-pixel electrode 210G of the first green sub-pixel Pg1 and a vertical distance hg2 from the substrate 100 to the sub-pixel electrode 210G of the second green sub-pixel Pg2. For example, Equation 3 may be expressed as Equation 4 below.

$$Δ {ϕ}_{21} = {ϕ}_{2} - {ϕ}_{1} = 2 \cdot \frac{2 π}{λ 1} n 0 \cdot Δ hg , ( Δ hg = h g 1 - h g 2 ) \qquad EQ . ( 4 )$$

In an embodiment, the first green light Lg1 and the second green light Lg2 have a phase difference that does not cancel and constructively interfere with each other. In an embodiment, a phase difference Δϕ₂₁ of the first green light Lg1 and the second green light Lg2 satisfies Equation 5 below.

$$Δ {ϕ}_{21} = \pm \frac{π}{2} + 2 m \cdot π , wherein m is an integer \qquad EQ . ( 5 )$$

In an embodiment, a difference Δhg between the vertical distance hg1 from the substrate 100 to the sub-pixel electrode 210G of the first green sub-pixel Pg1 and the vertical distance hg2 from the substrate 100 to the sub-pixel electrode 210G of the second green sub-pixel Pg2 satisfies Equation 6 below.

$$Δ h g = ( \pm \frac{1}{8 n 0} + \frac{m}{2 n 0} ) \cdot λ1 , wherein m is an integer \qquad EQ . ( 6 )$$

Because a display apparatus according to an embodiment includes a structure in which the vertical distance hg1 from the substrate 100 to the sub-pixel electrode 210G of the first green sub-pixel Pg1 differs from the vertical distance hg2 from the substrate 100 to the sub-pixel electrode 210G of the second green sub-pixel Pg2, the first green light Lg1 and the second green light Lg2 reflected from the adjacent first green sub-pixel Pg1 and second green sub-pixel Pg2 have a phase difference that does not cancel and constructively interfere with each other.

For example, because a display apparatus according to an embodiment includes a structure in which the difference Δhg between the vertical distance hg1 from the substrate 100 to the sub-pixel electrode 210G of the first green sub-pixel Pg1 and the vertical distance hg2 from the substrate 100 to the sub-pixel electrode 210G of the second green sub-pixel Pg2 is

$$( \pm \frac{1}{8 n 0} + \frac{m}{2 n 0} ) \cdot λ1$$

(m is an integer), a separation angle of multiple images formed by light reflected from the first green sub-pixel Pg1 and second green sub-pixel Pg2 is reduced by approximately half. Accordingly, because a difference in the separation angle of multiple images respectively formed by light reflected from green sub-pixels Pg, light reflected from blue sub-pixels Pb, and light reflected from red sub-pixels Pr is reduced, color separation is reduced. Accordingly, visibility of multiple images is reduced.

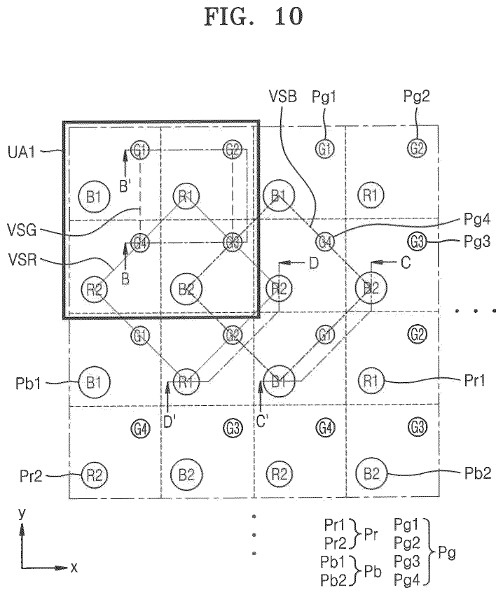

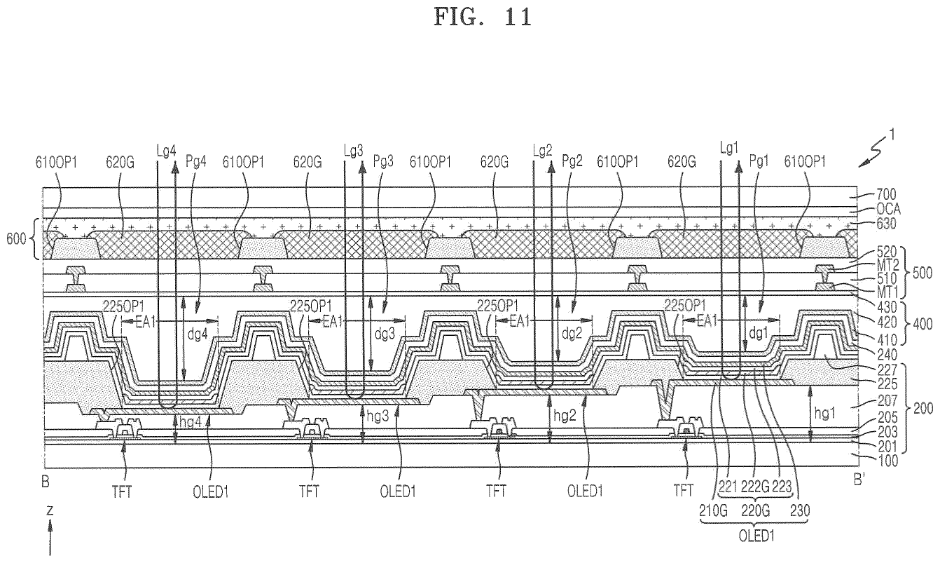

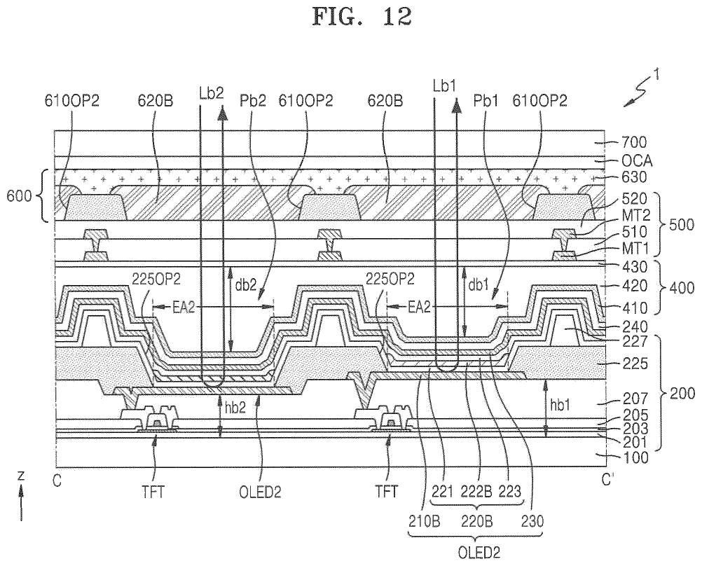

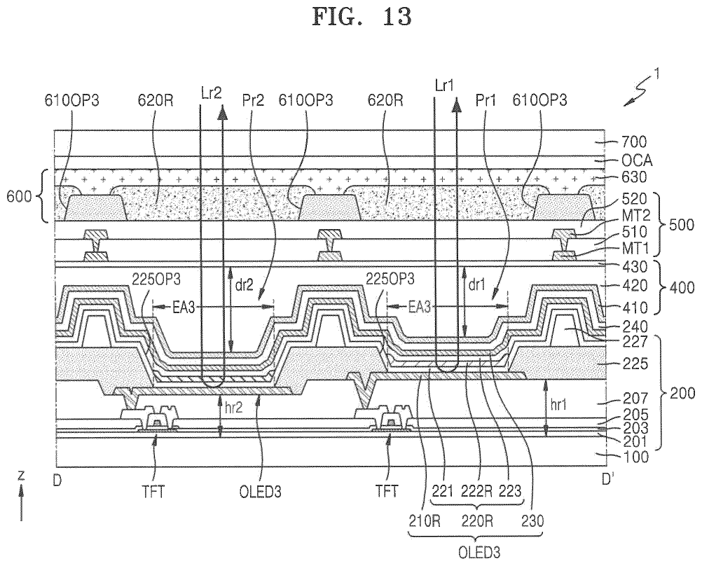

FIG. 10 is a plan view of a configuration of sub-pixels of a portion of a display apparatus according to an embodiment. FIGS. 11 to 13 are schematic cross-sectional views of a display apparatus according to an embodiment. FIG. 10 shows a phase difference pattern structure based on the sub-pixel configuration structure of FIG. 7. FIG. 11 is a schematic cross-sectional view of a display apparatus according to an embodiment, taken along line B-B′ of FIG. 10, FIG. 12 is a schematic cross-sectional view of a display apparatus according to an embodiment, taken along line C-C′ of FIG. 10, and FIG. 13 is a schematic cross-sectional view of a display apparatus according to an embodiment, taken along line D-D′ of FIG. 10.

Referring to FIG. 10, in an embodiment, the green sub-pixels Pg of the display apparatus 1 include the first green sub-pixel Pg1, the second green sub-pixel Pg2, a third green sub-pixel Pg3, and a fourth green sub-pixel Pg4. The first green sub-pixel Pg1, the second green sub-pixel Pg2, the third green sub-pixel Pg3, and the fourth green sub-pixel Pg4 that are adjacent to each other have a phase difference that does not cancel and constructively interfere with each other. The blue sub-pixels Pb of the display apparatus 1 include a first blue sub-pixel Pb1 and a second blue sub-pixel Pb2. The first blue sub-pixel Pb1 and the second blue sub-pixel Pb2 that are adjacent to each other have a phase difference that does not cancel and constructively interfere with each other. In addition, the red sub-pixels Pr of the display apparatus 1 include a first red sub-pixel Pr1 and a second red sub-pixel Pr2. The first red sub-pixel Pr1 and the second red sub-pixel Pr2 that are adjacent to each other have a phase difference that does not cancel and constructively interfere with each other.

A phase pattern structure of FIG. 10 includes a repeated configuration structure of a phase difference pattern unit block. Configurations of the first green sub-pixels Pg1, the second green sub-pixels Pg2, the third green sub-pixels Pg3, and the fourth green sub-pixels Pg4, the first blue sub-pixels Pb1 and the second blue sub-pixels Pb2, and the first red sub-pixels Pr1 and the second red sub-pixels Pr2 correspond to repeated configurations of a preset phase difference pattern unit block. In an embodiment, the phase difference pattern unit block is the same as the sub-pixel pattern unit block UA1.

In a repeated configuration structure of the phase difference pattern unit block, such as the sub-pixel pattern unit block UA1, the first green sub-pixel Pg1 to the fourth green sub-pixel Pg4 are respectively arranged on vertices in a virtual rectangle VSG with the red sub-pixel Pr or the blue sub-pixel Pb as a center point. Although FIG. 10 shows that the first green sub-pixel Pg1 and the third green sub-pixel Pg3 are respectively arranged on a first pair of opposite vertices in the virtual rectangle VSG, and the second green sub-pixel Pg2 and the fourth green sub-pixel Pg4 are respectively arranged on a second pair of opposite vertices in the virtual rectangle VSG, embodiments are not necessarily limited thereto. Other embodiments include various other configurations of the first green sub-pixel Pg1 to the fourth green sub-pixel Pg4 in one virtual rectangle VSG. The first blue sub-pixels Pb1 and the second blue sub-pixels Pb2 are respectively arranged on adjacent vertices of the virtual rectangle VSB with the green sub-pixel Pg as a center point. In addition, the first red sub-pixels Pr1 and the second red sub-pixels Pr2 are respectively arranged on adjacent vertices of a virtual rectangle VSR with the green sub-pixel Pg as a center point.

In an embodiment, the first green sub-pixel Pg1 may be denoted as a first-1 color sub-pixel, the second green sub-pixel Pg2 may be denoted as a first-2 color sub-pixel, the third green sub-pixel Pg3 may be denoted as a first-3 color sub-pixel, and the fourth green sub-pixel Pg4 may be denoted as a first-4 color sub-pixel. In an embodiment, the first blue sub-pixel Pb1 may be denoted as a second-1 color sub-pixel, and the second blue sub-pixel Pb2 may be denoted as a second-2 color sub-pixel. In an embodiment, the first red sub-pixel Pr1 may be denoted as a third-1 color sub-pixel, and the second red sub-pixel Pr2 may be denoted as a third-2 color sub-pixel.

FIG. 11 shows a cross-sectional structure of the first to fourth green sub-pixels Pg1, Pg2, Pg3, and Pg4 of FIG. 10. Referring to FIG. 11, in an embodiment, first green light Lg1 is reflected from the sub-pixel electrode 210G of the first green sub-pixel Pg1. Second green light Lg2 is reflected from the sub-pixel electrode 210G of the second green sub-pixel Pg2. Third green light Lg3 is reflected from the sub-pixel electrode 210G of the third green sub-pixel Pg3. Fourth green light Lg4 is reflected from the sub-pixel electrode 210G of the fourth green sub-pixel Pg4.

The vertical distance hg1 from the substrate 100 to the sub-pixel electrode 210G of the first green sub-pixel Pg1, the vertical distance hg2 from the substrate 100 to the sub-pixel electrode 210G of the second green sub-pixel Pg2, the vertical distance hg3 from the substrate 100 to the sub-pixel electrode 210G of the third green sub-pixel Pg3, and the vertical distance hg4 from the substrate 100 to the sub-pixel electrode 210G of the fourth green sub-pixel Pg4 differ from each other. For example, the vertical distance hg1, the vertical distance hg2, the vertical distance hg3, and the vertical distance hg4 have sequentially smaller values.

Of travel paths of the first green light Lg1, the second green light Lg2, the third green light Lg3, and the fourth green light Lg4, the thicknesses of the respective portions of the organic encapsulation layer 420 through which the first green light Lg1, the second green light Lg2, the third green light Lg3, and the fourth green light Lg4 pass differ from each other. Accordingly, the first green light Lg1, the second green light Lg2, the third green light Lg3, and the fourth green light Lg4 have a phase difference.

For example, when the first green light Lg1, the second green light Lg2, the third green light Lg3, and the fourth green light Lg4 have the same wavelength λ1 in a vacuum, and the refractive index of the organic encapsulation layer 420 is no, the first to fourth green light Lg1, Lg2, Lg3, and Lg4 have phases expressed by Equations 7 to 10 below, when passing through the organic encapsulation layer 420.

$${ϕ}_{1} = 2 \cdot \frac{2 π}{λ 1} n 0 \cdot dg 1 \qquad EQ . ( 7 )$$

$${ϕ}_{2} = 2 \cdot \frac{2 π}{λ 1} n 0 \cdot dg 2 \qquad EQ . ( 8 )$$

$${ϕ}_{3} = 2 \cdot \frac{2 π}{λ 1} n 0 \cdot dg 3 \qquad EQ . ( 9 )$$

$${ϕ}_{4} = 2 \cdot \frac{2 π}{λ 1} n 0 \cdot dg 4 \qquad EQ . ( 10 )$$

Here, dg1 denotes the thickness of a portion of the organic encapsulation layer 420 that corresponds to the first green sub-pixel Pg1, dg2 denotes the thickness of a portion of the organic encapsulation layer 420 that corresponds to the second green sub-pixel Pg2, dg3 denotes the thickness of a portion of the organic encapsulation layer 420 that corresponds to the third green sub-pixel Pg3, and dg4 denotes the thickness of a portion of the organic encapsulation layer 420 that corresponds to the fourth green sub-pixel Pg4. For example, the thickness dg1, the thickness dg2, the thickness dg3, and the thickness dg4 have sequentially greater values.

Accordingly, the first green light Lg1, the second green light Lg2, the third green light Lg3, and the fourth green light Lg4 have a phase difference. For example, the first green light Lg1, the second green light Lg2, the third green light Lg3, and the fourth green light Lg4 have phase differences as expressed by Equations 11 to 13, below.

$$Δ {ϕ}_{21} = {ϕ}_{2} - {ϕ}_{1} = 2 \cdot \frac{2 π}{λ1} n 0 \cdot Δ dg ( 1 ) , ( Δ dg ( 1 ) = dg 2 - dg 1 ) \qquad EQ . ( 11 )$$

$${Δϕ}_{31} = {ϕ}_{3} - {ϕ}_{1} = 2 \cdot \frac{2 π}{λ1} n 0 \cdot Δ dg ( 2 ) , ( Δ dg ( 2 ) = dg 3 - dg 1 ) \qquad EQ . ( 12 )$$

$${Δϕ}_{41} = {ϕ}_{4} - {ϕ}_{1} = 2 \cdot \frac{2 π}{λ1} n 0 \cdot Δ dg ( 3 ) , ( Δ dg ( 3 ) = dg 4 - dg 1 ) \qquad EQ . ( 13 )$$

Here, Δdg(1) is a difference in the thickness of portions of the organic encapsulation layer 420 through which the first green light Lg1 and the second green light Lg2 pass, Δdg(2) is a difference in the thickness of portions of the organic encapsulation layer 420 through which the first green light Lg1 and the third green light Lg3 pass, and Δdg(3) may correspond to a difference in the thickness of portions of the organic encapsulation layer 420 through which the first green light Lg1 and the fourth green light Lg4 pass.

For example, a difference in the thickness of the organic encapsulation layer 420 through which light reflected from the sub-pixel electrode of each sub-pixel passes corresponds to a vertical distance from the substrate 100 to the sub-pixel electrode of each sub-pixel. Accordingly, Equations 11 to 13 can be expressed as Equations 14 to 16, below.

$${Δϕ}_{21} = {ϕ}_{2} - {ϕ}_{1} = 2 \cdot \frac{2 π}{λ1} n 0 \cdot Δ hg ( 1 ) , ( Δ hg ( 1 ) = h g 1 - hg 2 ) \qquad EQ . ( 14 )$$

$${Δϕ}_{31} = {ϕ}_{2} - {ϕ}_{1} = 2 \cdot \frac{2 π}{λ1} n 0 \cdot Δ hg ( 2 ) , ( Δ hg ( 2 ) = h g 1 - h g 3 ) \qquad EQ . ( 15 )$$

$${Δϕ}_{41} = {ϕ}_{2} - {ϕ}_{1} = 2 \cdot \frac{2 π}{λ1} n 0 \cdot Δ hg ( 3 ) , ( Δ hg ( 3 ) = h g 1 - h g 4 ) \qquad EQ . ( 16 )$$

Here, Δhg(1) is a difference between the vertical distance hg1 from the substrate 100 to the sub-pixel electrode 210G of the first green sub-pixel Pg1 and the vertical distance hg2 from the substrate 100 to the sub-pixel electrode 210G of the second green sub-pixel Pg2, Δhg(2) is a difference between the vertical distance hg1 from the substrate 100 to the sub-pixel electrode 210G of the first green sub-pixel Pg1 and the vertical distance hg3 from the substrate 100 to the sub-pixel electrode 210G of the third green sub-pixel Pg3, and Δhg(3) corresponds to a difference between the vertical distance hg1 from the substrate 100 to the sub-pixel electrode 210G of the first green sub-pixel Pg1 and the vertical distance hg4 from the substrate 100 to the sub-pixel electrode 210G of the fourth green sub-pixel Pg4.

In an embodiment, the first green light Lg1 to the fourth green light Lg4 have a phase difference that does not cancel and constructively interfere with each other.

In an embodiment, a phase difference Δϕ₂₁ between the first green light Lg1 and the second green light Lg2, a phase difference Δϕ₃₁ between the first green light Lg1 and the third green light Lg3, and a phase difference Δϕ₄₁ between the first green light Lg1 and the fourth green light Lg4 satisfy Equations 17 to 19, below, or Equations 20 to 22, below.

$$Δ {ϕ}_{21} = \frac{π}{4} + 2 m \cdot π , wherein m is an integer \qquad EQ . ( 17 )$$

$$Δ {ϕ}_{31} = \frac{π}{2} + 2 m \cdot π , wherein m is an integer \qquad EQ . ( 18 )$$

$$Δ {ϕ}_{41} = \frac{3 π}{4} + 2 m \cdot π , wherein m is an integer \qquad EQ . ( 19 )$$

$$Δ {ϕ}_{21} = - \frac{π}{4} + 2 m \cdot π , wherein m is an integer \qquad EQ . ( 20 )$$

$$Δ {ϕ}_{31} = - \frac{π}{2} + 2 m \cdot π , wherein m is an integer \qquad EQ . ( 21 )$$

$$Δ {ϕ}_{41} = - \frac{3 π}{4} + 2 m \cdot π , wherein m is an integer \qquad EQ . ( 22 )$$

In an embodiment, the difference Δhg(1) between the vertical distance hg1 from the substrate 100 to the sub-pixel electrode 210G of the first green sub-pixel Pg1 and the vertical distance hg2 from the substrate 100 to the sub-pixel electrode 210G of the second green sub-pixel Pg2, the difference Δhg(2) between the vertical distance hg1 from the substrate 100 to the sub-pixel electrode 210G of the first green sub-pixel Pg1 and the vertical distance hg3 from the substrate 100 to the sub-pixel electrode 210G of the third green sub-pixel Pg3, and the difference Δhg(3) between the vertical distance hg1 from the substrate 100 to the sub-pixel electrode 210G of the first green sub-pixel Pg1 and the vertical distance hg4 from the substrate 100 to the sub-pixel electrode 210G of the fourth green sub-pixel Pg4 satisfy Equations 23 to 25, below, or Equations 26 to 28, below.

$$Δ hg ( 1 ) = hg 1 - hg 2 = ( \frac{1}{16 n 0} + \frac{m}{2 n 0} ) \cdot λ1 , wherein m is an integer \qquad EQ . ( 23 )$$

$$Δ hg ( 2 ) = hg 1 - hg 3 = ( \frac{1}{8 n 0} + \frac{m}{2 n 0} ) \cdot λ1 , wherein m is an integer \qquad EQ . ( 24 )$$

$$Δ hg ( 3 ) = hg 1 - hg 4 = ( \frac{3}{16 n 0} + \frac{m}{2 n 0} ) \cdot λ1 , wherein m is an integer \qquad EQ . ( 25 )$$

$$Δ hg ( 1 ) = hg 1 - hg 2 = ( - \frac{1}{16 n 0} + \frac{m}{2 n 0} ) \cdot λ1 , \qquad EQ . ( 26 )$$

$$wherein m is an integer$$

$$Δ hg ( 2 ) = hg 1 - hg 3 = ( - \frac{1}{8 n 0} + \frac{m}{2 n 0} ) \cdot λ1 , wherein m is an integer \qquad EQ . ( 27 )$$

$$Δ hg ( 3 ) = hg 1 - hg 4 = ( - \frac{3}{16 n 0} + \frac{m}{2 n 0} ) \cdot λ1 , \qquad EQ . ( 28 )$$

$$wherein m is an integer$$

FIG. 12 shows a cross-sectional structure of the first blue sub-pixel Pb1 and the second blue sub-pixel Pb2 of FIG. 10. Referring to FIG. 12, each of the first blue sub-pixel Pb1 and the second blue sub-pixel Pb2 includes the sub-pixel electrode 210B, the intermediate layer 220B, and the opposite electrode 230 that form the second organic light-emitting diode OLED2. First blue light Lb1 is reflected from the sub-pixel electrode 210B of the first blue sub-pixel Pb1. Second blue light Lb2 is reflected from the sub-pixel electrode 210B of the second blue sub-pixel Pb2.

A vertical distance hb1 from the substrate 100 to the sub-pixel electrode 210B of the first blue sub-pixel Pb1 differs from a vertical distance hb2 from the substrate 100 to the sub-pixel electrode 210B of the second blue sub-pixel Pb2. For example, the vertical distance hb1 is greater than the vertical distance hb2.

Of the travel paths of the first blue light Lb1 and the second blue light Lb2, the thicknesses of the respective portions of the organic encapsulation layer 420 through which the first blue light Lb1 and the second blue light Lb2 pass differ from each other. Accordingly, the first blue light Lb1 and the second blue light Lb2 have a phase difference.

For example, when the first blue light Lb1 and the second blue light Lb2 have the same wavelength λ2 in a vacuum, and the refractive index of the organic encapsulation layer 420 is n0, the first blue light Lb1 and the second blue light Lb2 have respective phases as expressed by Equations 29 and 30, below, when passing through the organic encapsulation layer 420.

$${ϕ}_{1 ′} = 2 \cdot \frac{2 π}{λ 2} n 0 \cdot db 1 \qquad EQ . ( 29 )$$

$${ϕ}_{2 ′} = 2 \cdot \frac{2 π}{λ 2} n 0 \cdot db 2 \qquad EQ . ( 30 )$$

Here, db1 is a thickness of a portion of the organic encapsulation layer 420 that corresponds to the first blue sub-pixel Pb1, and db2 is a thickness of a portion of the organic encapsulation layer 420 that corresponds to the second blue sub-pixel Pb2. For example, the thickness db1 is less than the thickness db2.

Accordingly, the first blue light Lb1 and the second blue light Lb2 have a phase difference. For example, the first blue light Lb1 and the second blue light Lb2 have a phase difference as expressed by Equation 31, below.

$${Δϕ}_{21 ′} = {ϕ}_{2 ′} - {ϕ}_{1 ′} = 2 \cdot \frac{2 π}{λ 2} n 0 \cdot Δ db , ( Δ db = db 2 - db 1 ) \qquad EQ . ( 31 )$$

Here, Δdb is a difference in the thickness of the respective portions of the organic encapsulation layer 420 through which the first blue light Lb1 and the second blue light Lb2 pass.

For example, the difference Δdb in the thickness of the respective portions of the organic encapsulation layer 420 through which the first blue light Lb1 and the second blue light Lb2 pass corresponds to a difference Δhb between a vertical distance hb1 from the substrate 100 to the sub-pixel electrode 210B of the first blue sub-pixel Pb1 and a vertical distance hb2 from the substrate 100 to the sub-pixel electrode 210B of the second blue sub-pixel Pb2. For example. Equation 31 can be expressed as Equation 32, below.

$${Δϕ}_{21 ′} = {ϕ}_{2 ′} - {ϕ}_{1 ′} = 2 \cdot \frac{2 π}{λ 2} n 0 \cdot Δ hb , ( Δ hb = hb 1 - hb 2 ) \qquad EQ . ( 32 )$$

In an embodiment, the first blue light Lb1 and the second blue light Lb2 have a phase difference that does not cancel and constructively interfere with each other. In an embodiment, a phase difference Δϕ₂₁, of the first blue light Lb1 and the second blue light Lb2 satisfies Equation 33, below.

$$Δ {ϕ}_{21 ′} = \pm \frac{π}{2} + 2 k \cdot π , wherein k is an integer \qquad EQ . ( 33 )$$

In an embodiment, a difference Δhb between the vertical distance hb1 from the substrate 100 to the sub-pixel electrode 210B of the first blue sub-pixel Pb1 and the vertical distance hb2 from the substrate 100 to the sub-pixel electrode 210B of the second blue sub-pixel Pb2 satisfies Equation 34, below.

$$Δ hb = ( \pm \frac{1}{8 n 0} + \frac{k}{2 n 0} ) \cdot λ 2 , wherein k is an integer \qquad EQ . ( 34 )$$

FIG. 13 shows a cross-sectional structure of the first red sub-pixel Pr1 and the second red sub-pixel Pr2 of FIG. 10. Referring to FIG. 13, in an embodiment, each of the first red sub-pixel Pr1 and the second red sub-pixel Pr2 includes the sub-pixel electrode 210R, the intermediate layer 220R, and the opposite electrode 230 that form the third organic light-emitting diode OLED3. First red light Lr1 is reflected from the sub-pixel electrode 210R of the first red sub-pixel Pr1. Second red light Lr2 is light reflected from the sub-pixel electrode 210R of the second red sub-pixel Pr2.

A vertical distance hr1 from the substrate 100 to the sub-pixel electrode 210R of the first red sub-pixel Pr1 differs from a vertical distance hr2 from the substrate 100 to the sub-pixel electrode 210R of the second red sub-pixel Pr2. For example, the vertical distance hr1 is greater than the vertical distance hr2.

Of the travel paths of the first red light Lr1 and the second red light Lr2, the thicknesses of respective portions of the organic encapsulation layer 420 through which the first red light Lr1 and the second red light Lr2 pass differ from each other. Accordingly, the first red light Lr1 and the second red light Lr2 have a phase difference.

For example, when the first red light Lr1 and the second red light Lr2 have the same wavelength λ3 in a vacuum, and the refractive index of the organic encapsulation layer 420 is n0, the first red light Lr1 and the second red light Lr2 have respective phases as expressed by Equations 35 and 36, below, when passing through the organic encapsulation layer 420.

$${ϕ}_{{1}^{″}} = 2 \cdot \frac{2 π}{λ 3} n 0 \cdot dr 1 \qquad EQ . ( 35 )$$

$${ϕ}_{{2}^{″}} = 2 \cdot \frac{2 π}{λ 3} n 0 \cdot dr 2 \qquad EQ . ( 36 )$$

Here, dr1 is a thickness of a portion of the organic encapsulation layer 420 that corresponds to the first red sub-pixel Pr1, and dr2 is a thickness of a portion of the organic encapsulation layer 420 that corresponds to the second red sub-pixel Pr2. For example, the thickness dr1 is less than the thickness dr2.

Accordingly, the first red light Lr1 and the second red light Lr2 have a phase difference. For example, the first red light Lr1 and the second red light Lr2 have a phase difference as expressed by Equation 37, below.

$${Δϕ}_{2 {1}^{″}} = {ϕ}_{{2}^{″}} - {ϕ}_{{1}^{″}} = 2 \cdot \frac{2 π}{λ3} n 0 \cdot Δ dr , ( Δ dr = dr 2 - dr 1 ) \qquad EQ . ( 37 )$$

Here, Δdr is a difference in the thickness of respective portions of the organic encapsulation layer 420 through which the first red light Lr1 and the second red light Lr2 pass.

For example, the difference Δdr in the thickness of the respective portions of the organic encapsulation layer 420 through which the first red light Lr1 and the second red light Lr2 pass corresponds to a difference Δhr between a vertical distance hr1 from the substrate 100 to the sub-pixel electrode 210R of the first red sub-pixel Pr1 and a vertical distance hr2 from the substrate 100 to the sub-pixel electrode 210R of the second red sub-pixel Pr2. For example, Equation 37 can be expressed as Equation 38, below.

$${Δϕ}_{2 {1}^{″}} = {ϕ}_{{2}^{″}} - {ϕ}_{{1}^{″}} = 2 \cdot \frac{2 π}{λ3} n 0 \cdot Δ hr , ( Δ hr = hr 1 - hr 2 ) \qquad EQ . ( 38 )$$

In an embodiment, the first red light Lr1 and the second red light Lr2 have a phase difference that does not cancel and constructively interfere with each other. In an embodiment, a phase difference Δϕ_{21″} of the first red light Lr1 and the second red light Lr2 satisfies Equation 39, below.

$$Δ {ϕ}_{{21}^{″}} = \pm \frac{π}{2} + 2 l \cdot π , wherein l is an integer \qquad EQ . ( 39 )$$

In an embodiment, a difference Δhr between the vertical distance hr1 from the substrate 100 to the sub-pixel electrode 210R of the first red sub-pixel Pr1 and the vertical distance hr2 from the substrate 100 to the sub-pixel electrode 210R of the second red sub-pixel Pr2 satisfies Equation 40, below.

$$Δ hr = ( \pm \frac{1}{8 n 0} + \frac{l}{2 n 0} ) \cdot λ 3 , wherein l is an integer \qquad EQ . ( 40 )$$

Because a display apparatus according to an embodiment includes a structure in which the vertical distance hg1 from the substrate 100 to the sub-pixel electrode 210G of the first green sub-pixel Pg1, the vertical distance hg2 from the substrate 100 to the sub-pixel electrode 210G of the second green sub-pixel Pg2, the vertical distance hg3 from the substrate 100 to the sub-pixel electrode 210G of the third green sub-pixel Pg3, and the vertical distance hg4 from the substrate 100 to the sub-pixel electrode 210G of the fourth green sub-pixel Pg4 differ from each other, the first green light Lg1 to the fourth green light Lg4 reflected from the adjacent first green sub-pixel Pg1 to fourth green sub-pixel Pg4 have a phase difference that does not cancel and constructively interfere with each other.

Because a display apparatus according to an embodiment includes a structure in which the vertical distance hb1 from the substrate 100 to the sub-pixel electrode 210B of the first blue sub-pixel Pb1 differs from the vertical distance hb2 from the substrate 100 to the sub-pixel electrode 210B of the second blue sub-pixel Pb2, the first blue light Lb1 and the second blue light Lb2 respectively reflected from the adjacent first blue sub-pixel Pb1 and second blue sub-pixel Pb2 have a phase difference that does not cancel and constructively interfere with each other.

In addition, because a display apparatus according to an embodiment includes a structure in which the vertical distance hr1 from the substrate 100 to the sub-pixel electrode 210R of the first red sub-pixel Pr1 differs from the vertical distance hr2 from the substrate 100 to the sub-pixel electrode 210R of the second red sub-pixel Pr2, the first red light Lr1 and the second red light Lr2 respectively reflected from the adjacent first red sub-pixel Pr1 and second red sub-pixel Pr2 have a phase difference that does not cancel and constructively interfere with each other.

Accordingly, all of the separation angles of multiple images respectively formed by light reflected from green sub-pixels Pg, light reflected from blue sub-pixels Pb, and light reflected from red sub-pixels Pr can be reduced. Compared to an above-described embodiment of FIG. 10, a separation angle of multiple images formed by light reflected from green sub-pixels Pg is reduced even more.

In addition, because a difference in the separation angle of multiple images respectively formed by light reflected from green sub-pixels Pg, light reflected from blue sub-pixels Pb, and light reflected from red sub-pixels Pr is reduced, color separation is reduced. Accordingly, visibility of multiple images is reduced.

FIG. 14 is a plan view of a configuration of sub-pixels of a portion of a display apparatus according to an embodiment.

Referring to FIG. 14, in an embodiment, a plurality of sub-pixels of the display apparatus include the green sub-pixel Pg, the blue sub-pixel Pb, and the red sub-pixel Pr. The red sub-pixels Pr, the blue sub-pixels Pb, and the green sub-pixels Pg have a repeated configuration structure. Sub-pixels of one color are arranged in the same column. For example, the red sub-pixels Pr are arranged in a first column c1, the blue sub-pixels Pb are arranged in a second column c2, and the green sub-pixels Pg are arranged in a third column c3. The red sub-pixel Pr, the blue sub-pixel Pb, and the green sub-pixel Pg are sequentially arranged in the same row. For example, the red sub-pixel Pr, the blue sub-pixel Pb, and the green sub-pixel Pg are arranged in a stripe structure.

The sub-pixels of the display apparatus have a repeated configuration structure of a sub-pixel pattern unit block UB1. For example, the configuration of the red sub-pixels Pr, the blue sub-pixels Pb, and the green sub-pixels Pg corresponds to a repeated configuration of a preset sub-pixel pattern unit block UB1. For example, the sub-pixel pattern unit block UB1 is a square.

In an embodiment, the sub-pixel pattern unit block UB1 includes the red sub-pixel Pr, blue sub-pixel Pb, and green sub-pixel Pg. The number of the red sub-pixels Pr, the blue sub-pixels Pb, and the green sub-pixels Pg in the sub-pixel pattern unit block UB1 is the same. For example, a number ratio of the red sub-pixels Pr, the blue sub-pixels Pb, and the green sub-pixels Pg in the sub-pixel pattern unit block UB1 is 1:1:1. FIG. 14 shows that the sub-pixel pattern unit block UB1 includes one red sub-pixel Pr, one blue sub-pixel Pb, and one green sub-pixel Pg and forms one pixel.

In the sub-pixel configuration structure of FIG. 14, the green sub-pixels Pg adjacent to each other are respectively arranged on the vertices of a virtual rectangle VSG′. The blue sub-pixels Pb adjacent to each other are respectively arranged on the vertices of a virtual rectangle VSB′. The red sub-pixels Pr adjacent to each other are respectively arranged on the vertices of a virtual rectangle VSR′. Green sub-pixels Pg adjacent to each other are arranged side-by-side in the x direction and y direction. Blue sub-pixels Pb adjacent to each other are arranged in the x direction and y direction. Red sub-pixels Pr adjacent to each other are arranged in the x direction and y direction. In an embodiment, the virtual rectangles VSG′, VSB′, and VSR′ are squares.

In an embodiment, a first distance d1′ between two adjacent green sub-pixels Pg, a second distance d2′ between two adjacent blue sub-pixels Pb, and a third distance d3′ between two adjacent red sub-pixels Pr are substantially equal to each other.

Considering an interval between the sub-pixels and the configuration structure of the sub-pixels, as compared to the sub-pixel configuration structure of FIG. 6, a separation angle of multiple images formed by light reflected from the green sub-pixel Pg, a separation angle of multiple images formed by light reflected from the red sub-pixel Pr, and a separation angle of multiple images formed by light reflected from the blue sub-pixel Pb are relatively similar to each other in a sub-pixel configuration structure of FIG. 14.

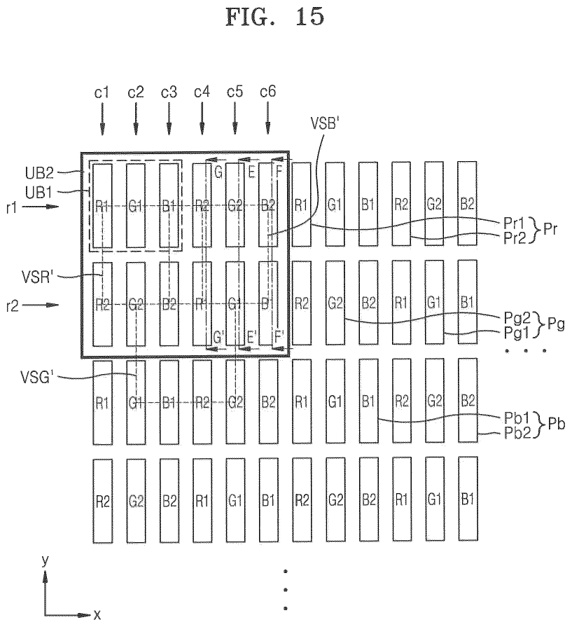

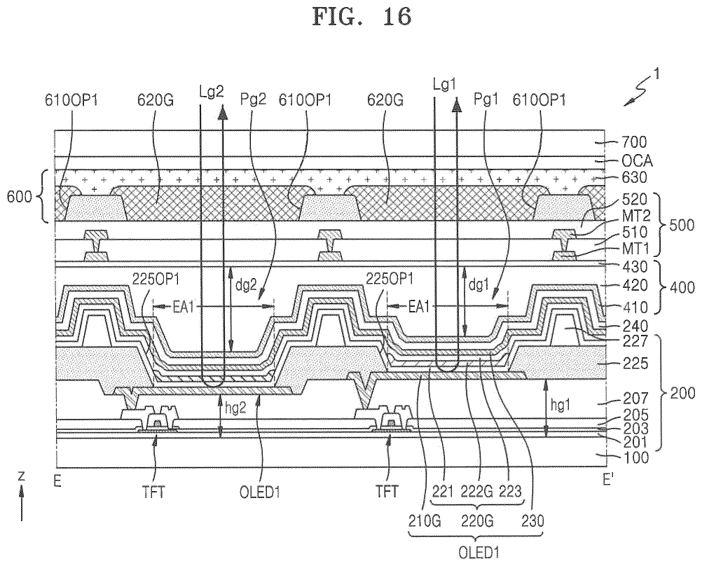

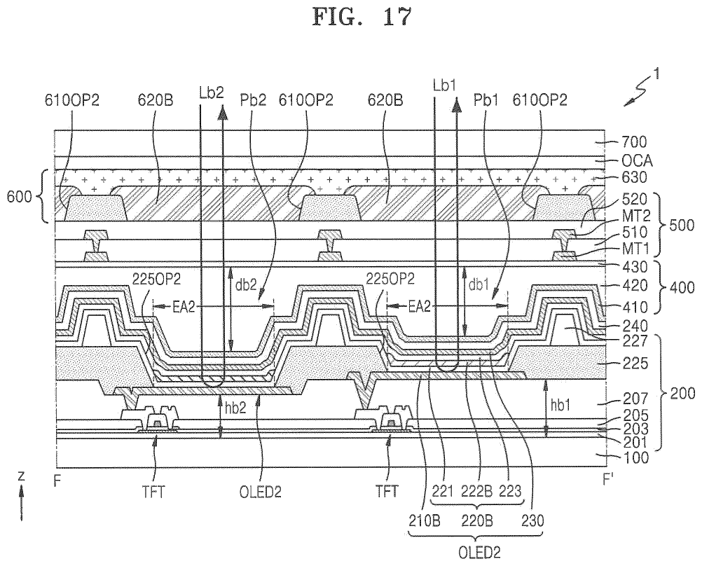

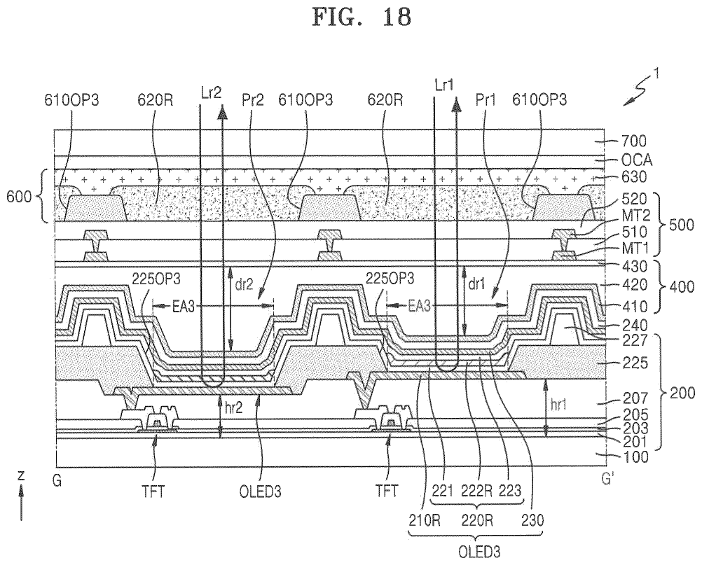

FIG. 15 is a plan view of a configuration of sub-pixels of a portion of a display apparatus according to an embodiment. FIG. 16 is a schematic cross-sectional view of a display apparatus according to an embodiment, FIG. 17 is a schematic cross-sectional view of a display apparatus according to an embodiment, and FIG. 18 is a schematic cross-sectional view of a display apparatus according to another embodiment. FIG. 15 shows a phase difference pattern structure based on a sub-pixel configuration structure of FIG. 14. FIG. 16 is a cross-sectional view of a display apparatus according to an embodiment, taken along line E-E′ of FIG. 15, FIG. 17 is a cross-sectional view of a display apparatus according to another embodiment, taken along line F-F′ of FIG. 15, and FIG. 18 is a cross-sectional view of a display apparatus according to another embodiment, taken along line G-G′ of FIG. 15.

Referring to FIG. 15, in an embodiment, the green sub-pixels Pg of the display apparatus 1 include the first green sub-pixel Pg1 and the second green sub-pixel Pg2. The first green sub-pixel Pg1 and the second green sub-pixel Pg2 that are adjacent to each other have a phase difference that does not cancel and constructively interfere with each other. The blue sub-pixels Pb of the display apparatus 1 include a first blue sub-pixel Pb1 and a second blue sub-pixel Pb2. The first blue sub-pixel Pb1 and the second blue sub-pixel Pb2 that are adjacent to each other have a phase difference that does not cancel and constructively interfere with each other. In addition, the red sub-pixels Pr of the display apparatus 1 include a first red sub-pixel Pr1 and a second red sub-pixel Pr2. The first red sub-pixel Pr1 and the second red sub-pixel Pr2 that are adjacent to each other have a phase difference that does not cancel and constructively interfere with each other.

A phase pattern structure of FIG. 15 includes a repeated configuration structure of a phase difference pattern unit block UB2. A configuration of the first green sub-pixels Pg1, the second green sub-pixels Pg2, the first blue sub-pixels Pb1, the second blue sub-pixels Pb2, the first red sub-pixels Pr1, and the second red sub-pixels Pr2 corresponds to a repeated configuration of a preset phase difference pattern unit block UB2. In an embodiment, the phase difference pattern unit block UB2 is a repeating configuration of the sub-pixel pattern unit blocks UB1, and the phase difference pattern unit block UB2 has a size that is an integer multiple of the size of the sub-pixel pattern unit block UB1. For example, the phase difference pattern unit block UB2 has a size that is 2×2 times the size of the sub-pixel pattern unit block UB1.

In the repeated configuration structure of the phase difference pattern unit blocks UB2, the first green sub-pixel Pg1 and the second green sub-pixel Pg2 may be respectively arranged on the opposite vertices of a virtual rectangle VSG′. The first blue sub-pixel Pb1 and the second blue sub-pixel Pb2 may be respectively arranged on the opposite vertices of a virtual rectangle VSB′. The first red sub-pixel Pr1 and the second red sub-pixel Pr2 may be respectively arranged on the opposite vertices of a virtual rectangle VSR′.

For example, the phase difference pattern unit block UB2 has 2 rows and 6 columns. The first red sub-pixels Pr1 are arranged in a first column c1 of a first row r1 and a fourth column c4 of a second row r2. The second red sub-pixels Pr2 are arranged in a fourth column c2 of the first row r1 and a first column c1 of the second row r2. The first green sub-pixels Pg1 are arranged in a second column c2 of the first row r1 and a fifth column c5 of the second row r2, and the second green subpixels Pg2 are arranged in a fifth column g5 of the first row r1 and a second column c2 of the second row r2. The first blue sub-pixels Pb1 are arranged in a third column c3 of the first row r1 and a sixth column c6 of the second row r2, and the second blue sub-pixels Pb2 are arranged in a sixth column c6 of the first row r1 and a third column c3 of the second row r2.

In an embodiment, the first green sub-pixel Pg1 may be denoted as a first-1 color sub-pixel, and the second green sub-pixel Pg2 may be denoted as a first-2 color sub-pixel. The first blue sub-pixel Pb1 may be denoted as a second-1 color sub-pixel, and the second blue sub-pixel Pb2 may be denoted as a second-2 color sub-pixel. The first red sub-pixel Pr1 may be denoted as a third-1 color sub-pixel, and the second red sub-pixel Pr2 may be denoted as a third-2 color sub-pixel.

FIG. 16 shows a cross-sectional structure of the first green sub-pixel Pg1 and the second green sub-pixel Pg2 of FIG. 15, according to an embodiment. The first green light Lg1 is reflected from the sub-pixel electrode 210G of the first green sub-pixel Pg1. The second green light Lg2 is reflected from the sub-pixel electrode 210G of the second green sub-pixel Pg2.

A vertical distance hg1 from the substrate 100 to the sub-pixel electrode 210G of the first green sub-pixel Pg1 differs from a vertical distance hg2 from the substrate 100 to the sub-pixel electrode 210G of the second green sub-pixel Pg2. For example, the vertical distance hg1 is greater than the vertical distance hg2.

The first green light Lg1 and the second green light Lg2 have a phase difference Δϕ₂₁. For example, the first green light Lg1 and the second green light Lg2 have a phase difference as expressed by Equation 41, below.

$${Δϕ}_{21} = {ϕ}_{2} - {ϕ}_{1} = 2 \cdot \frac{2 π}{λ1} n 0 \cdot Δ hg , ( Δ hg = hg 1 - hg 2 ) \qquad EQ . ( 41 )$$

Here, ϕ₁ is a phase of the first green light Lg1, ϕ₂ is a phase of the second green light Lg2, λ1 is a wavelength of the first green light Lg1 and the second green light Lg2 in a vacuum, no is a refractive index of the organic encapsulation layer, and Δhg is a difference between the vertical distance hg1 from the substrate 100 to the sub-pixel electrode 210G of the first green sub-pixel Pg1 and the vertical distance hg2 from the substrate 100 to the sub-pixel electrode 210G of the second green sub-pixel Pg2.

In an embodiment, the first green light Lg1 and the second green light Lg2 have a phase difference that does not cancel and constructively interfere with each other. In an embodiment, a phase difference Δϕ₂₁ of the first green light Lg1 and the second green light Lg2 satisfies Equation 42, below.

$$Δ {ϕ}_{21} = \pm \frac{π}{2} + 2 m \cdot π , wherein m is an integer \qquad EQ . ( 42 )$$

In an embodiment, a difference Δhg between the vertical distance hg1 from the substrate 100 to the sub-pixel electrode 210G of the first green sub-pixel Pg1 and the vertical distance hg2 from the substrate 100 to the sub-pixel electrode 210G of the second green sub-pixel Pg2 satisfies Equation 43, below.

$$Δ hg = ( \pm \frac{1}{8 n 0} + \frac{m}{2 n 0} ) \cdot λ 1 , wherein m is an integer \qquad EQ . ( 43 )$$

FIG. 17 shows a cross-sectional structure of the first blue sub-pixel Pb1 and the second blue sub-pixel Pb2 of FIG. 15, according to an embodiment. First blue light Lb1 is reflected from the sub-pixel electrode 210B of the first blue sub-pixel Pb1. Second blue light Lb2 is reflected from the sub-pixel electrode 210B of the second blue sub-pixel Pb2.

A vertical distance hb1 from the substrate 100 to the sub-pixel electrode 210B of the first blue sub-pixel Pb1 differs from a vertical distance hb2 from the substrate 100 to the sub-pixel electrode 210B of the second blue sub-pixel Pb2. For example, the vertical distance hb1 is greater than the vertical distance hb2.

The first green light Lb1 and the second green light Lb2 have a phase difference Δϕ_{21′}. For example, the first blue light Lb1 and the second blue light Lb2 have a phase difference as expressed by Equation 44, below.

$${Δϕ}_{21 ′} = {ϕ}_{2 ′} - {ϕ}_{1 ′} = 2 \cdot \frac{2 π}{λ 2} n 0 \cdot Δ hb , ( Δ hb = hb 1 - hb 2 ) \qquad EQ . ( 44 )$$

Here, ϕ₁, is a phase of the first blue light Lb1, ϕ₂, is a phase of the second blue light Lb2, λ2 is a wavelength of the first blue light Lb1 and the second blue light Lb2 in a vacuum, no is a refractive index of the organic encapsulation layer, and Δhb is a difference between the vertical distance hb1 from the substrate 100 to the sub-pixel electrode 210B of the first blue sub-pixel Pb1 and the vertical distance hb2 from the substrate 100 to the sub-pixel electrode 210B of the second blue sub-pixel Pb2.

In an embodiment, the first blue light Lb1 and the second blue light Lb2 have a phase difference that does not cancel and constructively interfere with each other. In an embodiment, a phase difference Δϕ₂₁, of the first blue light Lb1 and the second blue light Lb2 satisfies Equation 45, below.

$$Δ {ϕ}_{21 ′} = \pm \frac{π}{2} + 2 k \cdot π , wherein k is an integer \qquad EQ . ( 45 )$$

In an embodiment, a difference Δhb between the vertical distance hb1 from the substrate 100 to the sub-pixel electrode 210B of the first blue sub-pixel Pb1 and the vertical distance hb2 from the substrate 100 to the sub-pixel electrode 210B of the second blue sub-pixel Pb2 satisfies Equation 46, below.

$$Δ hb = ( \pm \frac{1}{8 n 0} + \frac{k}{2 n 0} ) \cdot λ2 , wherein k is an integer \qquad EQ . ( 46 )$$

FIG. 18 shows a cross-sectional structure of the first red sub-pixel Pr1 and the second red sub-pixel Pr2 of FIG. 15, according to an embodiment. First red light Lr1 is reflected from the sub-pixel electrode 210R of the first red sub-pixel Pr1. Second red light Lr2 is reflected from the sub-pixel electrode 210R of the second red sub-pixel Pr2.

A vertical distance hr1 from the substrate 100 to the sub-pixel electrode 210R of the first red sub-pixel Pr1 differs from a vertical distance hr2 from the substrate 100 to the sub-pixel electrode 210R of the second red sub-pixel Pr2. For example, the vertical distance hr1 is greater than the vertical distance hr2.

The first red light Lr1 and the second red light Lr2 have a phase difference Δϕ_{21″}. For example, the first red light Lr1 and the second red light Lr2 have a phase difference as expressed by Equation 47, below.

$$Δ {ϕ}_{{21}^{″}} = {ϕ}_{{2}^{″}} - {ϕ}_{{1}^{″}} = 2 \cdot \frac{2 π}{λ 3} n 0 \cdot Δ hr , ( Δ hr = hr 1 - hr 2 ) \qquad EQ . ( 47 )$$

Here, ϕ_{1″} is a phase of the first red light Lr1, ϕ_{2″} is a phase of the second red light Lr2, λ3 is a wavelength of the first red light Lr1 and the second red light Lr2 in a vacuum, no is a refractive index of the organic encapsulation layer, and Δhr is a difference between the vertical distance hr1 from the substrate 100 to the sub-pixel electrode 210R of the first red sub-pixel Pr1 and the vertical distance hr2 from the substrate 100 to the sub-pixel electrode 210R of the second red sub-pixel Pr2.

In an embodiment, the first red light Lr1 and the second red light Lr2 have a phase difference that does not cancel and constructively interfere with each other. In an embodiment, a phase difference Δϕ_{21″} of the first red light Lr1 and the second red light Lr2 satisfies Equation 48 below.

$$Δ {ϕ}_{{21}^{″}} = \pm \frac{π}{2} + 2 l \cdot π , wherein l is an integer \qquad EQ . ( 48 )$$

In an embodiment, a difference Δhr between the vertical distance hr1 from the substrate 100 to the sub-pixel electrode 210R of the first red sub-pixel Pr1 and the vertical distance hr2 from the substrate 100 to the sub-pixel electrode 210R of the second red sub-pixel Pr2 satisfies Equation 49, below.

$$Δ hr = ( \pm \frac{1}{8 n 0} + \frac{l}{2 n 0} ) \cdot λ3 , wherein l is an integer \qquad EQ . ( 49 )$$

Because a display apparatus according to an embodiment includes a structure in which the vertical distance hg1 from the substrate 100 to the sub-pixel electrode 210G of the first green sub-pixel Pg1 differs from the vertical distance hg2 from the substrate 100 to the sub-pixel electrode 210G of the second green sub-pixel Pg2, the first green light Lg1 and the second green light Lg2 reflected from the adjacent first green sub-pixel Pg1 and second green sub-pixel Pg2 have a phase difference that does not cancel and constructively interfere with each other.

Because a display apparatus according to an embodiment includes a structure in which the vertical distance hb1 from the substrate 100 to the sub-pixel electrode 210B of the first blue sub-pixel Pb1 differs from the vertical distance hb2 from the substrate 100 to the sub-pixel electrode 210B of the second blue sub-pixel Pb2, the first blue light Lb1 and the second blue light Lb2 reflected from the adjacent first blue sub-pixel Pb1 and second blue sub-pixel Pb2 have a phase difference that does not cancel and constructively interfere with each other.

In addition, because a display apparatus according to an embodiment includes a structure in which the vertical distance hr1 from the substrate 100 to the sub-pixel electrode 210R of the first red sub-pixel Pr1 differs from the vertical distance hr2 from the substrate 100 to the sub-pixel electrode 210R of the second red sub-pixel Pr2, the first red light Lr1 and the second red light Lr2 reflected from the adjacent first red sub-pixel Pr1 and second red sub-pixel Pr2 have a phase difference that does not cancel and constructively interfere with each other.

Accordingly, all of the separation angles of multiple images respectively formed by light reflected from green sub-pixels Pg, light reflected from blue sub-pixels Pb, and light reflected from red sub-pixels Pr can be reduced. Accordingly, because a difference in the separation angle of multiple images respectively formed by light reflected from green sub-pixels Pg, light reflected from blue sub-pixels Pb, and light reflected from red sub-pixels Pr is reduced even more, color separation is reduced. Accordingly, visibility of multiple images is reduced.

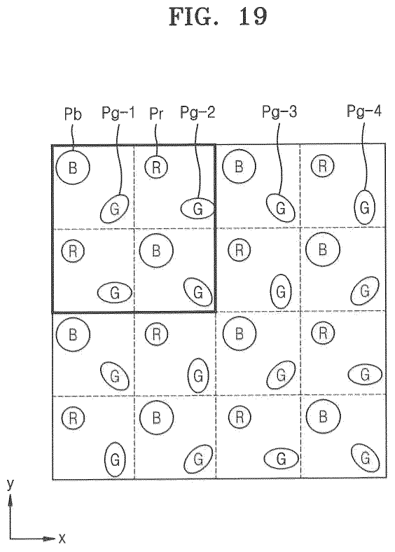

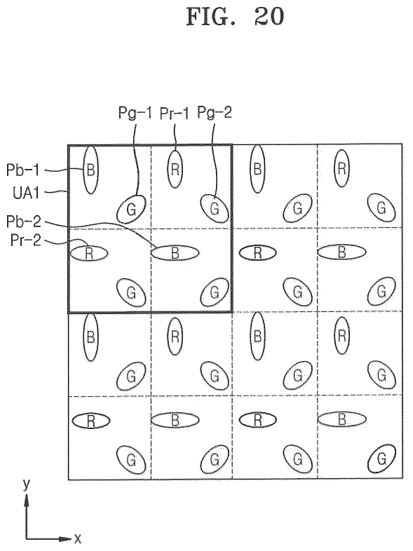

FIG. 19 is a plan view of a configuration of sub-pixels of a portion of a display apparatus according to an embodiment, and FIG. 20 is a plan view of a configuration of sub-pixels of a portion of a display apparatus according to an embodiment.

FIGS. 19 and 20 are modified embodiments of a sub-pixel configuration structure of FIG. 6 and differ in the planar shape of the green sub-pixels Pg, the blue sub-pixels Pb, and the red sub-pixels Pr. The phase difference pattern structure described above with reference to FIGS. 8 to 13 is applicable to a sub-pixel configuration structure of FIGS. 19 and 20.

Referring to FIG. 19, in an embodiment, the green sub-pixels Pg of the display apparatus 1 have an elliptical shape. The green sub-pixels Pg include a plurality of green sub-pixels Pg that have different elliptical axis angles. In an embodiment, the green sub-pixels Pg include a first-axis green sub-pixel Pg-1, a second-axis green sub-pixel Pg-2, a third-axis green sub-pixel Pg-3, and a fourth-axis green sub-pixel Pg-4. The first-axis green sub-pixel Pg-1 to the fourth-axis green sub-pixel Pg-4 have different elliptical axis angles, such as long axis angles. For example, a long axis of the first-axis green sub-pixel Pg-1 has an angle of about 45° with respect to the x axis, a long axis of the second-axis green sub-pixel Pg-2 has an angle parallel to the x axis, a long axis of the third-axis green sub-pixel Pg-3 has an angle of about −45° with respect to the x axis, and a long axis of the fourth-axis green sub-pixel Pg-4 has an angle of about 90° with respect to the x axis.

Although FIG. 19 shows first-axis green sub-pixels Pg-1 to fourth-axis green sub-pixels Pg-4 that have an elliptical shape with four different axis angles, embodiments are not necessarily limited thereto. For example, elliptically shaped green sub-pixels Pg with two or more and less than four, or more than 4 different axis angles may be included.

FIG. 19 illustrate an elliptically-shaped green sub-pixel Pg as an example. However, in an embodiment, each of the blue sub-pixel Pb or the red sub-pixel Pr may have an elliptical shape. For example, the description of the green sub-pixel Pg in FIG. 19 may be applied to the blue sub-pixel Pb or the red sub-pixel Pr.

Referring to FIG. 20, in an embodiment, at least two of the green sub-pixel Pg, the blue sub-pixel Pb, and the red sub-pixel Pr have an elliptical shape. For example, the green sub-pixel Pg, the blue sub-pixel Pb, and the red sub-pixel Pr each have an elliptical shape.

In an embodiment, at least two of the green sub-pixel Pg, the red sub-pixel Pr, and the blue sub-pixel Pb have an elliptical shape with different eccentricities. For example, the green sub-pixel Pg have an eccentricity that differs from those of the red sub-pixel Pr and the blue sub-pixel Pb. For example, the eccentricity of the shape of the green sub-pixel Pg is less than eccentricities of the shapes of the red sub-pixel Pr and the blue sub-pixel Pb. For example, the eccentricity of the green sub-pixel Pg is about 0.6, and the eccentricities of the red sub-pixel Pr and the blue sub-pixel Pb is about 0.8.

The green sub-pixels Pg include a plurality of green sub-pixels Pg with different elliptical axis angles. The blue sub-pixels Pb include a plurality of blue sub-pixels Pb with different elliptical axis angles. The red sub-pixels Pr include a plurality of red sub-pixels Pr with different elliptical axis angles.

In an embodiment, the green sub-pixels Pg include a first-axis green sub-pixel Pg-1 and a second-axis green sub-pixel Pg-2 with different elliptical axis angles. The blue sub-pixels Pb include a first-axis blue sub-pixel Pb-1 and a second-axis blue sub-pixel Pb-2 with different elliptical axis angles. The red sub-pixels Pr include a first-axis red sub-pixel Pr-1 and a second-axis red sub-pixel Pr-2 with different elliptical axis angles. An elliptical axis angle is a rotational angle of an ellipse axis with respect to the x axis. For example, a long axis of the first-axis green sub-pixel Pg-1 has an angle of about 45° with respect to the x axis, and a long axis of the second-axis green sub-pixel Pg-2 has an angle of about −45° with respect to the x axis. A long axis of the first-axis blue sub-pixel Pb-1 has an angle of about 90° with respect to the x axis, and a long axis of the second-axis blue sub-pixel Pb-2 is parallel to the x axis. A long axis of the first-axis red sub-pixel Pr-1 has an angle of about 90° with respect to the x axis, and a long axis of the second-axis red sub-pixel Pr-2 is parallel to the x axis.

In an embodiment, the first-axis green sub-pixels Pg-1 and the second-axis green sub-pixels Pg-2 are regularly arranged. The first-axis blue sub-pixels Pb-1 and the second-axis blue sub-pixels Pb-2 are regularly arranged. The first-axis red sub-pixels Pr-1 and the second-axis red sub-pixels Pr-2 are regularly arranged. A configuration of the first-axis green sub-pixels Pg-1, the second-axis green sub-pixels Pg-2, the first-axis blue sub-pixels Pb-1, the second-axis blue sub-pixels Pb-2, the first-axis red sub-pixels Pr-1, and the second-axis red sub-pixels Pr-2 corresponds to a repetitive configuration of shape pattern unit blocks having a size that is an integer multiple of the size of the preset sub-pixel pattern unit block UA1. For example, the shape pattern unit block corresponds to the sub-pixel pattern unit block UA1. However, embodiments are not necessarily limited thereto. In an embodiment, the first-axis green sub-pixels Pg-1 and the second-axis green sub-pixels Pg-2 are irregularly arranged, the first-axis blue sub-pixels Pb-1 and the second-axis blue sub-pixels Pb-2 are irregularly arranged, and the first-axis red sub-pixels Pr-1 and the second-axis red sub-pixels Pr-2 are irregularly arranged.

When elliptical sub-pixels with the same axis angle and eccentricity are regularly arranged, light blurring and multiple image phenomenon can occur due to diffraction of light reflected in a short axis direction of the ellipse. A display apparatus according to an embodiment that has at least some elliptically shaped sub-pixels may include a plurality of sub-pixels with different elliptical axis angles, and the plurality of sub-pixels may be regularly or irregularly arranged. In addition, in a display apparatus according to an embodiment, of the green sub-pixels, the blue sub-pixels, and the red sub-pixels, sub-pixels of at least two colors have elliptical shapes with different eccentricities from each other. Accordingly, multiple images formed by light reflected from the respective sub-pixels can be reduced.

According to an embodiment, a display apparatus is provided that has a reduced visibility of a multiple image caused by external light reflection and diffraction. However, the scope of embodiments of the disclosure is not limited by this effect.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A display apparatus, comprising:
a substrate;
a plurality of sub-pixels that include a first-color sub-pixel, a second-color sub-pixel, and a third-color sub-pixel that each include a sub-pixel electrode, an emission layer disposed on the sub-pixel electrode, and an opposite electrode disposed on the emission layer;
a bank layer that includes a plurality of lower openings that define an emission area in each of the plurality of sub-pixels;
an encapsulation layer disposed on the bank layer and that includes an organic encapsulation layer; and
a plurality of color filters disposed on the encapsulation layer and that include a first-color color filter, a second-color color filter, and a third-color color filter,
wherein the first-color sub-pixel includes a first-1 color sub-pixel and a first-2 color sub-pixel that emit light of a same color and are adjacent to each other, and
a vertical distance between the substrate and a sub-pixel electrode of the first-1 color sub-pixel differs from a vertical distance between the substrate and a sub-pixel electrode of the first-2 color sub-pixel.

2. The display apparatus of claim 1, further comprising a light-blocking layer disposed between the bank layer and the plurality of color filters and that includes a plurality of upper openings that respectively overlap the plurality of lower openings.

3. The display apparatus of claim 1, wherein the display apparatus does not include a polarizing film.

4. The display apparatus of claim 1, wherein
the plurality of sub-pixels include a repeated configuration structure of a sub-pixel pattern unit block that includes the first-color sub-pixel, the second-color sub-pixel, and the third-color sub-pixel, and
a number ratio of the first-color sub-pixel, the second-color sub-pixel, and the third-color sub-pixel in the sub-pixel pattern unit block is 2:1:1.

5. The display apparatus of claim 4, wherein
a difference Δhg between a first-1 vertical distance from the substrate to the sub-pixel electrode of the first-1 color sub-pixel and a first-2 vertical distance from the substrate to the sub-pixel electrode of the first-2 color sub-pixel satisfies a following equation:
$$Δ hg = hg 1 - hg 2 = ( \pm \frac{1}{8 n 0} + \frac{m}{2 n 0} ) \cdot λ1 ,$$
m is an integer,
no is a refractive index of the organic encapsulation layer,
λ1 is a wavelength of light reflected by the first-1 color sub-pixel and the first-2 color sub-pixel in a vacuum,
hg1 is the first-1 vertical distance from the substrate to the sub-pixel electrode of the first-1 color sub-pixel, and
hg2 is the first-2 vertical distance from the substrate to the sub-pixel electrode of the first-2 color sub-pixel.

6. The display apparatus of claim 4, wherein
the first-color sub-pixel further includes a first-3 color sub-pixel and a first-4 color sub-pixel that emit light of a same color and are adjacent to each other, and
a first-1 vertical distance from the substrate to the sub-pixel electrode of the first-1 color sub-pixel, a first-2 vertical distance from the substrate to the sub-pixel electrode of the first-2 color sub-pixel, a first-3 vertical distance from the substrate to a sub-pixel electrode of the first-3 color sub-pixel, and a first-4 vertical distance from the substrate to a sub-pixel electrode of the first-4 color sub-pixel are different from each other.

7. The display apparatus of claim 6, wherein
a difference Δhg(1) between the first-1 vertical distance from the substrate to the sub-pixel electrode of the first-1 color sub-pixel and the first-2 vertical distance from the substrate to the sub-pixel electrode of the first-2 color sub-pixel, a difference Δhg(2) between the first-1 vertical distance from the substrate to the sub-pixel electrode of the first-1 color sub-pixel and the first-3 vertical distance from the substrate to the sub-pixel electrode of the first-3 color sub-pixel, and a difference Δhg(3) between the first-1 vertical distance from the substrate to the sub-pixel electrode of the first-1 color sub-pixel and the first-4 vertical distance from the substrate to the sub-pixel electrode of the first-4 color sub-pixel, satisfy equations as follows:
$$Δ hg ( 1 ) = hg 1 - hg 2 = ( \frac{\pm 1}{16 n 0} + \frac{m}{2 n 0} ) \cdot λ1 ,$$
wherein m is an integer,
$$Δ hg ( 2 ) = hg 1 - hg 3 = ( \frac{\pm 1}{8 n 0} + \frac{m}{2 n 0} ) \cdot λ1 ,$$
wherein m is an integer,
$$Δ hg ( 3 ) = hg 1 - hg 4 = ( \frac{\pm 3}{16 n 0} + \frac{m}{2 n 0} ) \cdot λ1 ,$$
wherein m is an integer, wherein
n0 is a refractive index of the organic encapsulation layer,
λ1 is a wavelength of light reflected by the first-1 color sub-pixel to the first-4 color sub-pixel in a vacuum,
hg1 is the first-1 vertical distance from the substrate to the sub-pixel electrode of the first-1 color sub-pixel,
hg2 is the first-2 vertical distance from the substrate to the sub-pixel electrode of the first-2 color sub-pixel, and
hg3 is the first-3 vertical distance from the substrate to the sub-pixel electrode of the first-3 color sub-pixel, hg4 is the first-4 vertical distance from the substrate to the sub-pixel electrode of the first-4 color sub-pixel.

8. The display apparatus of claim 4, wherein
the second-color sub-pixel includes a second-1 color sub-pixel and a second-2 color sub-pixel that emit light of a same color and are adjacent to each other, and
a second-1 vertical distance from the substrate to a sub-pixel electrode of the second-1 color sub-pixel differs from a second-2 vertical distance from the substrate to a sub-pixel electrode of the second-2 color sub-pixel.

9. The display apparatus of claim 4, wherein
the third-color sub-pixel includes a third-1 color sub-pixel and a third-2 color sub-pixel that emit light of a same color and are adjacent to each other, and
a third-1 vertical distance from the substrate to a sub-pixel electrode of the third-1 color sub-pixel differs from a third-2 vertical distance from the substrate to a sub-pixel electrode of the third-2 color sub-pixel.

10. The display apparatus of claim 8, wherein
a difference Δhb between the second-1 vertical distance from the substrate to the sub-pixel electrode of the second-1 color sub-pixel and the second-2 vertical distance from the substrate to the sub-pixel electrode of the second-2 color sub-pixel satisfies a following equation:
$$Δ hb = hb 1 - hb 2 = ( \pm \frac{1}{8 n 0} + \frac{k}{2 n 0} ) \cdot λ2$$
no is a refractive index of the organic encapsulation layer,
λ2 is a wavelength of light reflected by the second-1 color sub-pixel and the second-2 color sub-pixel in a vacuum,
hb1 is a second-1 vertical distance from the substrate to the sub-pixel electrode of the second-1 color sub-pixel, and
hb2 is a second-2 vertical distance from the substrate to the sub-pixel electrode of the second-2 color sub-pixel.

11. The display apparatus of claim 9, wherein
a difference Δhr between the third-1 vertical distance from the substrate to the sub-pixel electrode of the third-1 color sub-pixel and the third-2 vertical distance from the substrate to the sub-pixel electrode of the third-2 color sub-pixel satisfies a following equation:
$$Δ hr = hr 1 - hr 2 = ( \pm \frac{1}{8 n 0} + \frac{l}{2 n 0} ) \cdot λ3 ,$$
n0 is a refractive index of the organic encapsulation layer,
λ3 is a wavelength of light reflected by the third-1 color sub-pixel and the third-2 color sub-pixel in a vacuum,
hr1 is a third-1 vertical distance from the substrate to the sub-pixel electrode of the third-1 color sub-pixel, and
hr2 is a third-2 vertical distance from the substrate to the sub-pixel electrode of the third-2 color sub-pixel.

12. The display apparatus of claim 1, wherein
the plurality of sub-pixels include a repeated configuration structure of a sub-pixel pattern unit block that includes the first-color sub-pixel, the second-color sub-pixel, and the third-color sub-pixel, and
a number ratio of the first-color sub-pixel, the second-color sub-pixel, and the third-color sub-pixel in the sub-pixel pattern unit block is 1:1:1.

13. The display apparatus of claim 12, wherein
a difference Δhg between a first-1 vertical distance from the substrate to the sub-pixel electrode of the first-1 color sub-pixel and a first-2 vertical distance from the substrate to the sub-pixel electrode of the first-2 color sub-pixel satisfies a following equation;
$$Δ hg = hg 1 - hg 2 = ( \pm \frac{1}{8 n 0} + \frac{m}{2 n 0} ) \cdot λ1 ,$$
no is a refractive index of the organic encapsulation layer,
λ1 is a wavelength of light reflected by the first-1 color sub-pixel and the first-2 color sub-pixel in a vacuum,
hg1 is the first-1 vertical distance from the substrate to the sub-pixel electrode of the first-1 color sub-pixel, and
hg2 is the first-2 vertical distance from the substrate to the sub-pixel electrode of the first-2 color sub-pixel.

14. The display apparatus of claim 12, wherein
the second-color sub-pixel includes a second-1 color sub-pixel and a second-2 color sub-pixel that emit light of a same color and are adjacent to each other, and
a second-1 vertical distance from the substrate to a sub-pixel electrode of the second-1 color sub-pixel differs from a second-2 vertical distance from the substrate to a sub-pixel electrode of the second-2 color sub-pixel.

15. The display apparatus of claim 12, wherein
the third-color sub-pixel includes a third-1 color sub-pixel and a third-2 color sub-pixel that emit light of a same color and adjacent to each other, and
a third-1 vertical distance from the substrate to a sub-pixel electrode of the third-1 color sub-pixel differs from a third-2 vertical distance from the substrate to a sub-pixel electrode of the third-2 color sub-pixel.

16. The display apparatus of claim 14, wherein
a difference Δhb between the second-1 vertical distance from the substrate to the sub-pixel electrode of the second-1 color sub-pixel and the second-2 vertical distance from the substrate to the sub-pixel electrode of the second-2 color sub-pixel satisfies a following equation:
$$Δ hb = hb 1 - hb 2 = ( \pm \frac{1}{8 n 0} + \frac{k}{2 n 0} ) \cdot λ2 ,$$
wherein k is an integer,
n0 is a refractive index of the organic encapsulation layer,
λ2 is a wavelength of light reflected by the second-1 color sub-pixel and the second-2 color sub-pixel in a vacuum,
hb1 is a second-1 vertical distance from the substrate to the sub-pixel electrode of the second-1 color sub-pixel, and
hb2 is a second-2 vertical distance from the substrate to the sub-pixel electrode of the second-2 color sub-pixel.

17. The display apparatus of claim 15, wherein
a difference Δhr between the third-1 vertical distance from the substrate to the sub-pixel electrode of the third-1 color sub-pixel and the third-2 vertical distance from the substrate to the sub-pixel electrode of the third-2 color sub-pixel satisfies a following equation:
$$Δ hr = hr 1 - hr 2 = ( \pm \frac{1}{8 n 0} + \frac{l}{2 n 0} ) \cdot λ3 ,$$
n0 is a refractive index of the organic encapsulation layer,
λ3 is a wavelength of light reflected by the third-1 color sub-pixel and the third-2 color sub-pixel in a vacuum,
hr1 is a third-1 vertical distance from the substrate to the sub-pixel electrode of the third-1 color sub-pixel, and
hr2 is a third-2 vertical distance from the substrate to the sub-pixel electrode of the third-2 color sub-pixel.

18. The display apparatus of claim 1, wherein the first-color color filter, the second-color color filter, and the third-color color filter overlap each other in a region between the sub-pixel electrodes of the plurality of sub-pixels.

19. The display apparatus of claim 1, wherein
the first-color sub-pixel has an elliptical shape in a plan view, and
the first-color sub-pixel includes a first-axis sub-pixel and a second-axis sub-pixel that have different elliptical axis angles from each other.

20. The display apparatus of claim 1, wherein
each of the first-color sub-pixel, the second-color sub-pixel, and the third-color sub-pixel has an elliptical shape in a plan view, and
at least two of the first-color sub-pixel, the second-color sub-pixel, or the third-color sub-pixel have different elliptical eccentricities from each other.
